(19) United States
(12) Patent Application Publication
(10) Pub. No.: US 2025/0038476 A1
(43) Pub. Date: Jan. 30, 2025

(54) THERMALLY COMPENSATED WAVELENGTH TUNABLE LASERS

(71) Applicant: Freedom Photonics LLC, Goleta, CA (US)

(72) Inventors: Gordon Barbour Morrison, Summerland, CA (US); Donald J. Kebort, Santa Barbara, CA (US)

(21) Appl. No.: 18/784,721

(22) Filed: Jul. 25, 2024

Related U.S. Application Data
(60) Provisional application No. 63/516,460, filed on Jul. 28, 2023.

(51) Int. Cl. H01S 5/06; H01S 5/0239; H01S 5/068; H01S 5/14

(52) U.S. Cl. CPC H01S 5/0612; H01S 5/0239; H01S 5/06804; H01S 5/06808; H01S 5/141

(57) ABSTRACT

An optical apparatus comprising a heat compensating device and a light generating optoelectronic device in thermal communication with each other. The heat compensating device is configured to provide heat compensation for the light generating optoelectronic device. An electrical circuitry provides first electrical signals to the light generating device and second electrical signals to the heat compensating device. The electrical circuitry is configured to adjust at least the second electrical signals to control a temperature of the light generating device. The electrical circuitry can adjust the second electrical signals using a feedback signal indicative of a measured wavelength of light generated by the light generating device. Adjusting the first electrical signals via different paths in a wavelength map can be used to calibrate the electrical circuitry so as to reduce or eliminate thermally induced hysteresis effects when tuning or scanning the wavelength of the light generating device.

### INCORPORATION BY REFERENCE TO ANY PRIORITY APPLICATIONS

This application claims the benefit of priority of U.S. Provisional Application No. 63/516,460 titled “THERMALLY COMPENSATED WAVELENGTH TUNABLE LASERS”, which was filed on Jul. 28, 2023, the entire disclosure of which is expressly incorporated herein by reference.

This application is related to U.S. patent application Ser. No. 18/361,421, filed Jul. 28, 2023, entitled “MULTIPLE OPTOELECTRONIC DEVICES WITH THERMAL COMPENSATION”, which is a continuation in part of U.S. patent application Ser. No. 18/167,777, filed Feb. 10, 2023, entitled “MULTIPLE OPTOELECTRONIC DEVICES WITH THERMAL COMPENSATION”, which is a continuation of U.S. patent application Ser. No. 17/062,462, filed Oct. 2, 2020, entitled “MULTIPLE OPTOELECTRONIC DEVICES WITH THERMAL COMPENSATION”, and issued Feb. 14, 2023 as U.S. Pat. No. 11,581,700, which claims the benefit of priority to U.S. Provisional Application No. 62/910,826 filed on Oct. 4, 2019 titled “MULTIPLE OPTOELECTRONIC DEVICES WITH THERMAL COMPENSATION”. The entire contents of each of the above-identified patent applications are hereby incorporated by reference herein.

### BACKGROUND

### Field of the Invention

Various embodiments of this application relate to the field of wavelength tunable semiconductor lasers and more particularly reducing thermal effects and their impact on the accuracy and predictability of wavelength tuning.

### Description of the Related Art

Lasers are widely used in telecommunications, sensing, test and measurement, as well as other applications. Some such applications call for the use of wavelength tunable lasers that output light having a tuned wavelength. Some such applications can benefit from accuracy and predictability, and repeatability of the tuned wavelengths. Many wavelength tunable lasers, however, suffer from inaccuracies, hysteresis effects, and instabilities resulting from thermal effects during a wavelength tuning or scanning process. Accordingly, it would be advantageous to reduce or eliminate these thermal effects using thermal compensation.

### BRIEF DESCRIPTION OF THE DRAWINGS

In the following description of the various embodiments, reference is made to the accompanying drawings which form a part hereof, and in which is shown by way of illustration various embodiments of the device. It is to be understood that other embodiments may be utilized and structural changes may be made.

FIG. 1A illustrates an example apparatus comprising a first optoelectronic device, a second optoelectronic device and an electrical circuitry where the first optoelectronic device is in optical communication with an optical system.

FIG. 1B illustrates an example apparatus comprising a first optoelectronic device, a second optoelectronic device and an electrical circuitry where the first optoelectronic device is in optical communication with an optical system via an optical coupler.

FIG. 2A illustrates a top view of an example chip with a first tunable laser and a second tunable laser where each tunable laser include two mirrors, a phase section, a gain section, an optical amplifier, and a rear absorber.

FIG. 2B illustrates a top view of an example chip with a first tunable laser transmitter and a second tunable laser transmitter where each tunable laser transmitter include two mirrors, a phase section, a gain section, an optical amplifier, a rear absorber and a modulator.

FIG. 3 illustrates example relative changes to injection electrical currents provide to the front mirror, back mirror, and phase section of a tunable laser or tunable laser transmitter to tune the wavelength of an optical signal generated by the tunable laser transmitter.

FIG. 4 illustrates heat generated by a section of a first optoelectronic device, heat generated by a section of a second optoelectronic device and combined heat generated by the two sections when injection electrical currents provided to the section of the first optoelectronic device and to the section of the second optoelectronic device are modulated with opposite phase.

FIG. 5A schematically illustrates a configuration of a chip comprising two optoelectronic devices mounted on a carrier and wire bonded to the electrical ports of a carrier such that device on the left is wire bonded to ports for the active device, and the device on the right is wire bonded to ports for the compensation heat control.

FIG. 5B schematically illustrates a configuration of a chip comprising two optoelectronic devices mounted on a carrier and wire bonded to the electrical ports of a carrier such that the device on the right is wire bonded to ports for the active device, and the device on the left is wire bonded to ports for the compensation heat control.

FIG. 6 is a flow diagram of an example fabrication method of an apparatus comprising two optoelectronic devices by selecting and connecting first optoelectronic device to a circuitry for optoelectronic control and selecting and connecting a second optoelectronic device to a circuitry for producing heat compensation for the first optoelectronic device.

FIG. 7A schematically illustrates heat dissipation rate by an optoelectronic device as a function of the electrical current (I) provided to the optoelectronic device.

FIG. 7B schematically illustrates an apparatus comprising a heat dissipating optoelectronic device in thermal communication with a light generating optoelectronic device.

FIGS. 8A and 8B schematically illustrate two example temporal variations of the electrical current (I₂) provided to a heat compensating device and the resulting changes in the heat transfer rate (H₂₁) from the heat compensating device to an optoelectronic device. A) The electrical current is increased to provide heat to the optoelectronic device. B) The electrical current is reduced to absorb heat from the optoelectronic device. The solid and dashed lines represent electrical current variations that result in fast and delayed thermal control respectively.

FIG. 8C shows temporal variation of electric current (I₁) provided to a section of the first optoelectronic device (e.g., the light generating device) and two example temporal variations of modified (e.g., pre-emphasized) electric current (I₂) provided to a section of the second optoelectronic device (e.g., the heat compensating device) to stabilize the temperature of the first optoelectronic device.

FIG. 9 schematically illustrates a system comprising an optoelectronic device thermally controlled by a heat compensating device via a feedback loop and based on a measured wavelength or wavelength change of light generated by the optoelectronic device.

FIG. 10A schematically illustrates an example wavelength monitoring device that generates multiple optical outputs having optical powers dependent on a wavelength of input light.

FIG. 10B schematically illustrates the optical power output from three different output ports of the wavelength monitoring device shown in FIG. 10A as a function of the wavelength of light received by the input port of the wavelength monitoring device.

FIG. 10C schematically illustrates an integrated photonic circuit depicting an example waveguide arrangement for the wavelength monitoring device shown in FIG. 10A.

FIG. 10D schematically illustrates a simplified photonic circuit diagram for the integrated photonic circuit shown in FIG. 10C.

FIG. 10E schematically illustrates the optical power output from three different output ports of the wavelength monitoring device shown in FIG. 10C as a function of relative optical frequency of light received by the input port.

FIG. 11A illustrates an example wavelength map obtained by raster scanning wavelength control currents provided to the front and back mirrors (a wavelength tunable laser) in a forward direction by scanning the electric current provided to the front mirror in forward direction and the back mirror from small values to larger values (as shown in the bottom panel). The black regions represent mode boundaries.

FIG. 11B illustrates another example wavelength map obtained by raster scanning wavelength control currents provided to the front and back mirrors of an optoelectronic light source a wavelength tunable laser) in a reverse direction by scanning the electric current provided to the front mirror in backward direction and decreasing the electric current provided to the back mirror from large values to smaller values (as shown in the bottom panel). The black regions represent mode boundaries and the resulting modal zones.

FIG. 11C illustrates an example wavelength difference map (also referred to as wavelength hysteresis map) obtained by subtracting the wavelength map in FIG. 11B from the wavelength map in FIG. 11A. The black regions depict either mode boundaries or regions where a difference between respective wavelengths in the wavelength maps shown in FIG. 11A and FIG. 11B is larger than 10 pm (a selected threshold value).

FIG. 11D illustrates the example wavelength difference map shown in FIG. 11A with numerically labeled modal zones. Numerical values represent average wavelengths within each modal zone and smaller values represent larger wavelengths.

FIG. 12A illustrates an example hysteresis behavior of the wavelength of light output by an optoelectronic device (e.g., a wavelength tunable laser) with respect to an electrical current provided to a wavelength tuning section (e.g., a reflector) of the optoelectronic device in the absence of thermal compensation.

FIG. 12B is an example portion of a wavelength map illustrating the wavelength of light output by an optoelectronic device (e.g., a wavelength tunable laser) as a function of two electrical currents provided to two wavelength tuning sections (e.g., front and back mirrors).

FIG. 12C illustrates examples of current paths that may be used during calibration of the apparatus shown in FIG. 7B or the system shown in FIG. 9.

FIG. 12D illustrates examples of measured wavelength variations at an end of a selected current path in a wavelength map, before and after a calibration step.

FIG. 12E illustrates an example current path in a wavelength map defined by specified discrete wavelength values.

FIG. 13 is a flow diagram illustrating an example method of calibrating an electrical circuitry configured to control properties light generated by an optoelectronic device by at least controlling signals provided to a second optoelectronic device that is thermal communication with the first optoelectronic device.

FIG. 14 is a flow diagram illustrating another example method of calibrating an electrical circuitry configured to control wavelength of light generated by an optoelectronic device by at least controlling signals provided to a second optoelectronic device that is thermal communication with the first optoelectronic device.

### DETAILED DESCRIPTION

Certain embodiments described herein advantageously utilize space on an optoclectronic chip (e.g., substrate; wafer) that would otherwise be wasted to improve the yield of usable devices. For example, the empty space on a substrate not occupied by a first optoelectronic device (e.g., a tunable laser or tunable laser transmitter) can be utilized by fabricating at least one second optoelectronic device (e.g., similar or identical to the first optoelectronic device) on the same chip (e.g., substrate; wafer) in thermal communication with the first optoelectronic device and using a selected one of the first and the at least one second optoelectronic devices to generate optical signals (e.g., selected based on the optical properties and/or performance of the first and the at least one second optoelectronic devices) and using the other of the first and at least one second optoelectronic device to provide thermal compensation for the first optoelectronic device. By including the at least one second optoelectronic device on the available excess real estate and allowing one of the two or more optoelectronic devices to be selected to generate optical signals, the chip yield can be increased, and manufacturing costs can be decreased. Additionally, the optoelectronic device selected for providing heat compensation may improve the performance of the optoelectronic, device selected for generating optical signals, by stabilizing a temperature of one or more sections of the optoelectronic device selected for generating optical signals. In some examples, stabilizing the temperature of one or more sections of the optoelectronic device selected for generating optical signals, may facilitate tuning or adjusting the wavelength of optical signals (e.g., enable monotonous wavelength tuning within a given wavelength range). In some examples, stabilizing the temperature of one or more sections of the optoelectronic device selected for generating optical signals, may improve the stability of a power or an intensity of the generated optical signals. For example, the heat compensation provided by the optoelectronic device, selected for heat compensation, may maintain the optical intensity or optical power within ±1%, ±2%, ±3%, ±4%, ±5%, ±6%, ±7%, ±8%, ±10% or ±20% of a target optical intensity or optical power, or any range between any of these values. In some examples, stabilizing the temperature of one or more sections of the optoelectronic device, selected for generating optical signals, may improve the stability of a wavelength of optical signals. For example, the heat compensation provided by the second optoelectronic device may maintain the wavelength of the optical signals within ±1%, ±2%, ±3%, ±4%, ±5%, ±6%, ±7%, ±8%, +10% or ±20% of a target wavelength, or any range between any of these values.

Certain embodiments described herein provide an advantageous improvement in yield. For example, if a defect in one of the two or more optoelectronic devices occurs, another non-defective optoelectronic device of the two or more optoelectronic devices can be used for generating optical signals, while the defective optoelectronic device can be used (e.g., primarily or solely) for thermal compensation of the non-defective optoelectronic device. For another example, if one of the two or more optoelectronic devices is sub-optimal, another optimal optoelectronic device of the two or more optoelectronic devices can be used to generate optical signals (e.g., packaged to provide optical signals), while the sub-optimal optoelectronic device is used (e.g., primarily or solely) for thermal compensation of the optimal optoelectronic device that is generating optical signals. For still another example, the two or more optoelectronic devices can have different designs from one another (e.g., variations of parameter space for the different optoelectronic devices), and the optoelectronic device having a preferred, better, best, etc. operation (e.g., such as higher or lower based on a selected metric, for example, temporal variation of an optical intensity or optical power and/or wavelength of the optical signals generated by the optoelectronic device.) among the two or more optoelectronic devices can be used to generate optical signals (e.g., packaged to provide optical signals), while an optoelectronic device not having the preferred, better or best operation (e.g., such as higher or lower based on a selected metric, for example, temporal variation of an optical intensity or optical power and/or wavelength of the optical signals generated by the optoelectronic device) is used (e.g., primarily or solely) for thermal compensation of the optoelectronic device having the preferred, better or best optical operation and that is generating optical signals. For yet another example, the two or more optoelectronic devices can have different designs from one another, and the optoelectronic device having the desired operation can be used (e.g., packaged to provide optical signals), while an optoelectronic device not having the desired operation is used (e.g., primarily or solely) for thermal compensation of the optoelectronic device having the desired operation, resulting in an advantageous improvement in inventory management.

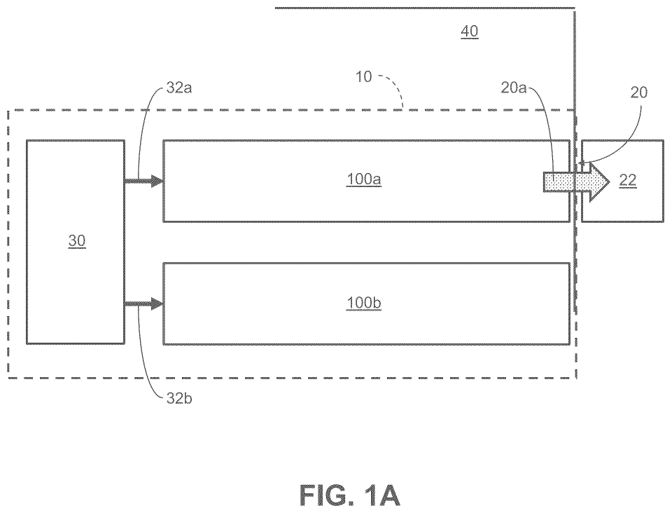

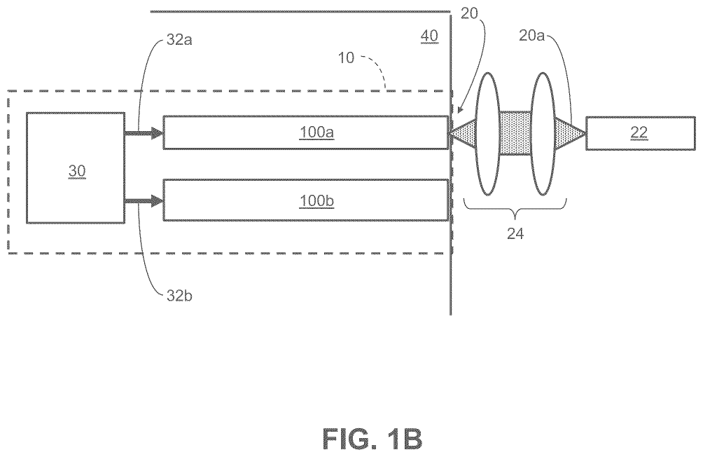

FIGS. 1A and 1B schematically illustrate an example apparatus 10 in accordance with certain embodiments described herein. The apparatus 10 comprises at least a first optoelectronic device 100a and a second optoelectronic device 100b, the first and second optoelectronic devices 100a, 100b in thermal communication with one another (e.g., the first and second optoelectronic devices 100a, 100b are formed on the same chip 40 (e.g., substrate; wafer). The apparatus 10 further comprises an optical output port 20 in optical communication with the first optoelectronic device 100a and configured configure to output light or optical signals generated by the first optoelectronic device 100a. In some embodiments, the optical output port may be configured to be in optical communication with an optical system 22 (e.g., via an optical coupler 24).

The apparatus 10 further comprises electrical circuitry 30 in electrical communication with the first optoelectronic device 100a, the electrical circuitry 30 configured to provide first electrical signals 32a to the first optoelectronic device 100a, the first optoelectronic device 100a responsive to the first electrical signals 32a by generating optical signals 20a and heat. The electrical circuitry 30 is further in electrical communication with the second optoelectronic device 100b, the electrical circuitry 30 configured to provide second electrical signals 32b to the second optoelectronic device 100b, the second optoelectronic device 100b responsive to the second electrical signals 32b by generating heat. The electrical circuitry 30 is configured to controllably adjust the first electrical signals 32a and the second electrical signals 32b to controllably adjust a temperature of the first optoelectronic device 100a.

In certain embodiments, one or both of the first optoelectronic device 100a and the second optoelectronic device 100b comprises a tunable laser. For example, the tunable laser can include a waveguide with active and passive sections including at least one mirror (or optical reflector) comprising an optical grating, at least one optical gain section, and at least one output facet. In some examples, the output facet may be partially reflecting. For another example, the tunable laser can include two mirrors (optical reflectors), a phase section, and an optical gain section. For still another example, the tunable laser can include a semiconductor optical amplifier (SOA) (e.g., the first optoelectronic device 100a can include a distributed feedback laser with an SOA output, where wavelength tuning, and power tuning can be thermally compensated by the second optoelectronic device 100b) and/or an electro-absorption modulator. In certain other embodiments, one or both of the first optoelectronic device 100a and the second optoelectronic device 100b may comprise a tunable laser transmitter (e.g., a tunable laser with an optical modulator).

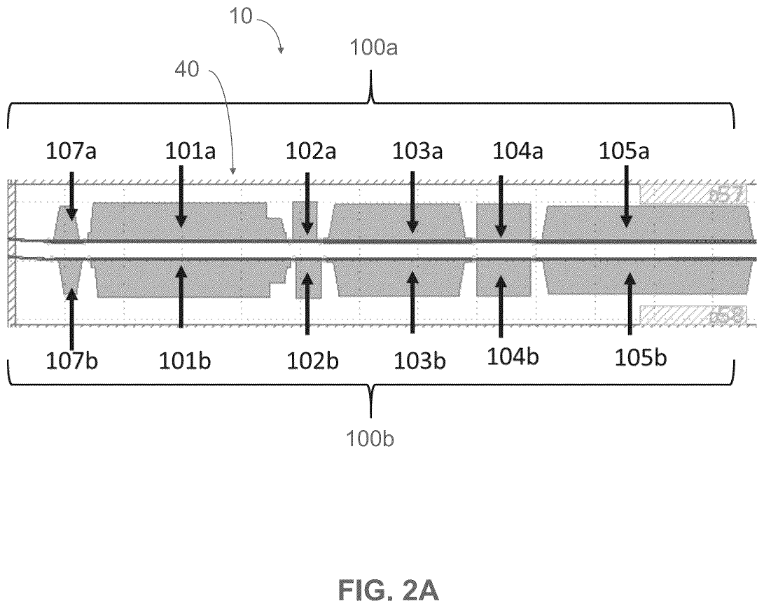

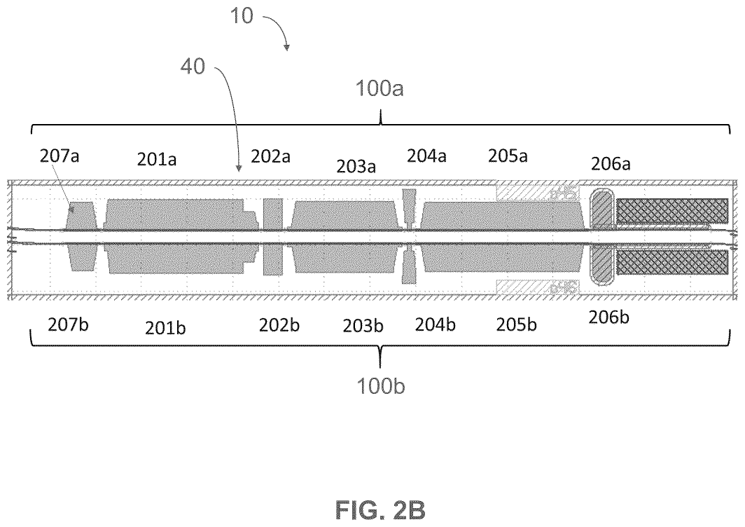

FIG. 2A schematically illustrates a top view of an example apparatus 10 in accordance with certain embodiments described herein. In FIG. 2A, the first and second optoelectronic devices 100a, 100b each comprise a tunable laser. In FIG. 2B, the first and second optoelectronic devices 100a, 100b each comprise a tunable laser transmitter. In FIGS. 2A and 2B, the two optoelectronic devices 100a, 100b are fabricated on a single chip 40. For example, the single chip 40 can have a minimum fabrication size (e.g., due to manufacturing constraints, the chip 40 would not be any smaller in footprint if it comprised only a single optoelectronic device). In certain embodiments, the two optoelectronic devices 100a, 100b (e.g., tunable lasers; tunable laser transmitters) are included on a single chip 40 that would otherwise have supported a single optoelectronic device. Similarly, in certain embodiments, the two optoelectronic devices 100a, 100b (e.g., tunable lasers; tunable laser transmitters) are included on a single chip 40 that would otherwise have supported two or more optoelectronic devices.

As schematically illustrated by FIG. 2A, in some embodiments, the first optoelectronic device 100a comprises a tunable laser including two first mirrors 101a, 104a, a first phase section 102a, a first gain section 103a, a first semiconductor optical amplifier 105a, and a first rear absorber 107a. The second optoelectronic device 100b can be fabricated in a portion of the chip 40 that would otherwise be unused and the second optoelectronic device 100b can be similar (e.g., identical) to the first optoelectronic device 100a. For example, the second optoelectronic device 100b can comprise components that would be equally useful as a tunable laser, which as shown in FIG. 2A, can include two second mirrors 101b, 104b, a second phase section 102b, a second gain section 103b, a second semiconductor optical amplifier 105b, and a second rear absorber 107b. As schematically illustrated by FIG. 2B, the first optoelectronic device 100a comprises a tunable laser transmitter including two first mirrors 201a, 204a, a first phase section 202a, a first gain section 203a, a first semiconductor optical amplifier 205a, a first rear absorber 207a, and a first modulator 206a. The second optoelectronic device 100b can be fabricated in a portion of the chip 40 that would otherwise be unused and the second optoelectronic device 100b can be similar (e.g., have the same components of the similar or the same or identical size and/or shape or other characteristics such as electrical, material, or spatial characteristics) to the first optoelectronic device 100a. For example, the second optoelectronic device 100b can comprise components that would be equally useful as a tunable laser transmitter, which as shown in FIG. 2B, can include two second mirrors 201b, 204b, a second phase section 202b, a second gain section 203b, a second semiconductor optical amplifier 205b, a second rear absorber 207b, and a second modulator 206b. In some embodiments, an optoelectronic device may comprise plurality of sections. In some such embodiments, each section may comprise one or more components (e.g., mirror, optical reflector, phase shifter, optical amplifier, optical absorber, optical gain and the like). In some cases, one or more temperature sensors may be included (e.g., monolithically integrated) with an optoelectronic device. In some such cases, one or more sections, possibly most or even each section, may include a temperature sensor that may be used to monitor or measure the temperature of that section. A temperature sensor can be, for example, a thermistor, a thermocouple, or a semiconductor temperature sensor (e.g., a semiconductor junction).

Due to the aspect ratios of the first and second optoelectronic devices 100a, 100b, and the constraints imposed by packaging and cleaving systems, the practical and convenient chip size is much larger than the size of the individual first optoelectronic device 100a. Thus, there may be a significant amount of space on the chip 40 that is unused and does not include any optoelectronic components and/or functional blocks included in the first optoelectronic device 100a.

In certain embodiments, the two optoelectronic devices 100a, 100b are tested (e.g., prior to further packaging). If a defect in one of the two optoelectronic devices 100a, 100b renders it unusable for generating optical signals, it is possible that the other of the two optoelectronic device 100a, 100b is usable for generating optical signals, and further packaging comprises configuring the usable optoelectronic device for electrical connection (e.g., in electrical communication with circuitry 30) and for optical connection (e.g., in optical communication with optical system 22), while the unusable optoelectronic device is not configured for generating optical signals. In certain embodiments, the two optoelectronic devices 100a, 100b are tested (e.g., prior to further packaging), and the optoelectronic device with certain optical performance may be selected for optical connection, while the other optoelectronic device ultimately is not used for generating optical signals.

In certain embodiments, if the first optoelectronic device 100a is tested and meets all requirements, testing of the second optoelectronic device 100b can be omitted (e.g., is not required), and the first optoelectronic device 100a can selected to be electrically connected to an electrical circuit and to be in optical communication with an optical system, while the second optoelectronic device 100b, although it may be operational (e.g., capable of generating optical signals), may not be configured for generating optical signals. In some examples, the second optoelectronic device may generate light or optical signals but not being optical communication with an optical system. In some examples, current may be provided only to selected sections of the second optoelectronic device (e.g., to generate heat and provide heat compensation for the second optoelectronic device).

In certain embodiments, designing and manufacturing optoelectronic devices (e.g., tunable lasers; tunable laser transmitters) can advantageously provide two slightly different optoelectronic devices (e.g., different versions of the same optoelectronic device) that can be simultaneously fabricated. For example, during a testing phase in which the two optoelectronic devices 100a, 100b are tested (e.g., by measuring an intensity, power or a wavelength of optical signals generated by the optoelectronic device), one of the two optoelectronic devices 100a, 100b can be selected based on the test results and on the desired application. The one of the two optoelectronic devices with better optical performance can be selected to be further configured to be in optical communication with an optical system 22 (e.g., via an output optical fiber) while the other non-selected optoelectronic device, although present on the chip 40 and in the device package, is not in optical communication with the optical system 22. In certain such embodiments, both the selected optoelectronic device and the non-selected optoelectronic device are provided with electrical connections and input electrical signals, with the non-selected optoelectronic device used to provide temperature control for the selected optoelectronic device. In some examples, an optical performance may be measured at least in part based on a measured intensity or power of the optoelectronic device and/or a measured wavelength of the optoelectronic device. In some examples an optical performance may be measured at least in part based on a temporal variation of measured intensity or power of the optoelectronic device and/or a temporal variation of the measured wavelength of the optoelectronic device. In some cases, a better performance is a measured performance that is different from another measured performance by a threshold value.

In certain embodiments, operation of the optoelectronic device that is in optical communication with the optical system 22 via the optical output port 20 (e.g., the first optoelectronic device 100a) comprises adjusting (e.g., changing; tuning; modifying) at least one electrical signal 32a (e.g., electrical currents) provided to at least one component of the first optoelectronic device 100a. Such adjustments of the at least one electrical current or voltage provided to the optoelectronic device can be used to, for example, adjust a wavelength of the optical signals generated by the optoelectronic device or to adjust the intensity or power of light output by the optoelectronic device. In some cases, an adjustment of the at least one electrical current or voltage provided to the optoelectronic device may comprise modulating the electrical current of the electrical voltage at a modulation frequency. In some examples the modulation frequency can be from 1 Hz to 100 Hz, 100 Hz to 1 KHz, 1 KHz to 100 KHz, 100 KHz to 1 MHz, 1 MHz to 100 MHz, 100 MHz to 1 GHz, 1 GHz to 10 GHz, or 10 GHz to 50 GHz or any range formed by any of these values.

In some cases, an adjustment of the at least one electrical current or voltage provided to the optoelectronic device can be used to compensate for aging of an active material in at least one component (e.g., gain section; phase section; one or more mirrors) over the lifetime of the optoelectronic device.

In some embodiments, at least one injection electrical current can be adjusted so as to sweep the first optoelectronic device 100a (e.g., Vernier-tuned tunable laser) through a continuum of wavelengths within a predetermined wavelength range. FIG. 3 schematically illustrates example relative changes to injection electrical currents provided to the front mirror 104a, back mirror 101a, and phase section 102a of a first optoelectronic device 100a in accordance with certain embodiments described herein. This ramping of the injection electrical currents provided to the front mirror 104a, back mirror 101a, and the phase section 102a can be complex, and in certain embodiments, electrical currents provided to the gain section 103a and/or the first SOA 105a are also tuned to maintain power as the wavelength is adjusted. FIG. 3 shows the variation of the wavelength 404 of an example optoelectronic device (e.g., the first optoelectronic device 100a) as a result of adjusting the electrical current 401 provided to the phase section 102a for phase tuning, the electrical current 402 provided to the front mirror 104a, and the electrical current 403 provided to the back mirror 101a. In this plot, the x-axis represent points in time, the left-most y-axis represents the magnitude of electrical currents 401 provided to the phase section 102a for phase tuning, the electrical current 402 provided to the front mirror 104a, and the electrical current 403 provided to the back mirror 101, and the right-most y-axis represents the wavelength 404 of the first optoelectronic device 100a. FIG. 3 shows that various currents provided to an optoelectronic device (e.g., the first optoelectronic device) may need to be adjusted in a complex manner in order to change the wavelength monotonously (e.g., as a linearly decreasing function) while maintaining the optical output power constant or within a limited or predefined range.

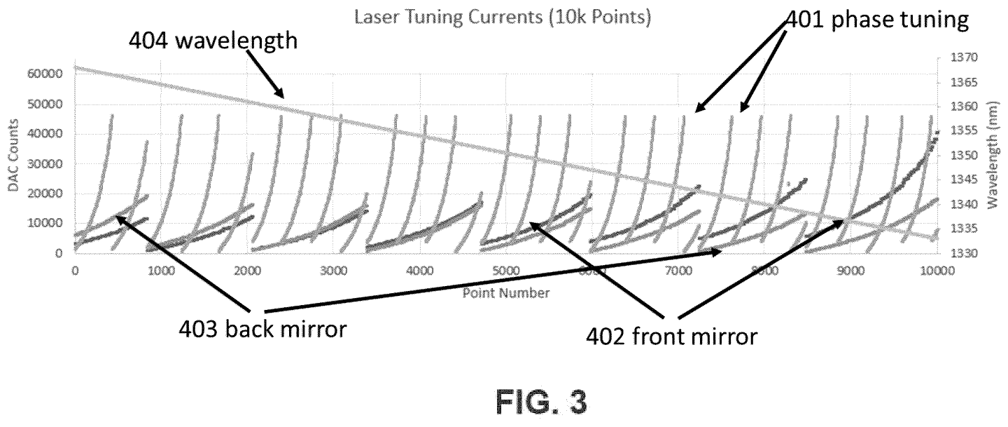

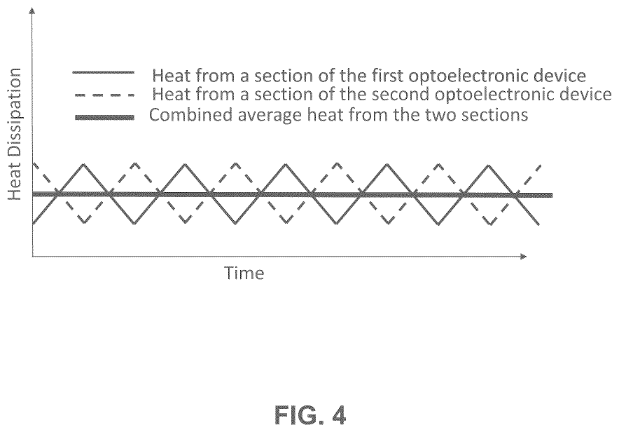

These changing injection electrical currents provided to various portions of the first optoelectronic device 100a induce corresponding temperature changes over time. Such temperature changes could affect the operation of the first optoelectronic device 100a. In some examples, these changing temperatures may interfere with the wavelength adjustment process and make it difficult to control the wavelength of the first optoelectronic device. Advantageously, in certain embodiments, the second optoelectronic device 100b may be used to reduce (e.g., prevent; mitigate; minimize) these temperature-induced effects by providing thermal compensation. In some embodiments, one or more second injection currents may be provided to one or more sections or components of the second optoelectronic device such that the heat exchange between the first optoelectronic device and the second optoelectronic device results in a constant or nearly constant temperature of one or more sections or the components of the first optoelectronic device that are adjusted using one or more first injection currents. For example, FIG. 4 schematically illustrates the temporal variation of heat dissipated or generated by a section of the first optoelectronic device and a section of the second optoelectronic device. In this example, the heat from each section could be generated as a result of modulating a first injection electrical current provided to a section of the first optoelectronic device 100a (e.g., a laser with its optical output 20 in optical communication with an optical system 22 and in electrical communication with the electrical circuitry 30) and modulating the second injection electrical current provided to a section of the second optoelectronic device 100b (e.g., a laser that is not in optical communication with the optical system 22 and that is in electrical communication with the electrical circuitry 30) in accordance with certain embodiments described herein. While the second optoelectronic device 100b is not in optical communication with the optical system 22 (e.g., optical signals generated by the second optoelectronic device 100b are unused), at least one injection electrical current provided to the second optoelectronic device 100b is used to compensate the changing heat generated by the first optoelectronic device 100a (e.g., to keep the temperature of the first optoelectronic device 100a within a predetermined range). As shown in FIG. 4, the summed heat generated and dissipated by both the first optoelectronic device 100a and the second optoelectronic device 100b is controlled (e.g., substantially constant; adjusted among different values) over time such that the temperature of the first optoelectronic device 100a is controlled (e.g., substantially constant; adjusted to a desired value or adjusted to remain within a particular range) over time.

In certain embodiments, the substantially constant temperature is maintained regardless of the drive currents being sourced to the first optoelectronic device 100a (e.g., the selected laser), which as described above, can change as a function of time. As one or more electrical currents provided to one or more sections of the first optoelectronic device 100a (e.g., currents to one or more sections 101a-107a) are driven downwards or upwards from a nominal value to tune or control the first optoelectronic device 100a (e.g., the laser wavelength, power, and/or side mode suppression ratio), one or more electrical currents provided to one or more corresponding sections of the second optoelectronic device 100b (e.g., currents to one or more sections 101b-107b) are driven by a similar amount upwards or downwards (or by an amount having a similar effect) in the opposite direction. Thus, in certain embodiments, by providing an opposite bias to the corresponding section of the second optoelectronic device 100b that is adjacent to the section of the first optoelectronic device 100a having the changing bias, the thermal load in any region of the chip 40 can remain substantially constant so that the temperature of the first optoelectronic device 100a remains substantially constant (e.g., does not vary significantly with changes to the device bias).

In certain embodiments, the first optoelectronic device 100a and the second optoelectronic device 100b are paired (e.g., mirror imaged) to one another on the chip 40 (and/or grouped and/or sufficiently close) such that the waveguides of the two optoelectronic devices 100a, 100b are in thermal communication with one another (e.g., spaced by a distance in a range of 2 microns to 100 microns; spaced by less than 100 microns) to improve uniformity of constant thermal load. In certain embodiments, the injection currents in one or more pairs of local sections (e.g., sections 101a, 101b; sections 102a, 102b; etc.) are balanced to compensate one another, thereby promoting or ensuring constant thermal load and enhanced temperature stability. In certain embodiments, thermal compensation is provided by pairing only a subset (e.g., one or two) of the sections 101a-107a of the first optoelectronic device 100a with corresponding sections 101b-107b of the second optoelectronic device 100b, while in certain other embodiments, thermal compensation is provided by pairing all of the sections 101a-107a of the first optoelectronic device 100a with corresponding sections 101b-107b of the second optoelectronic device 100b.

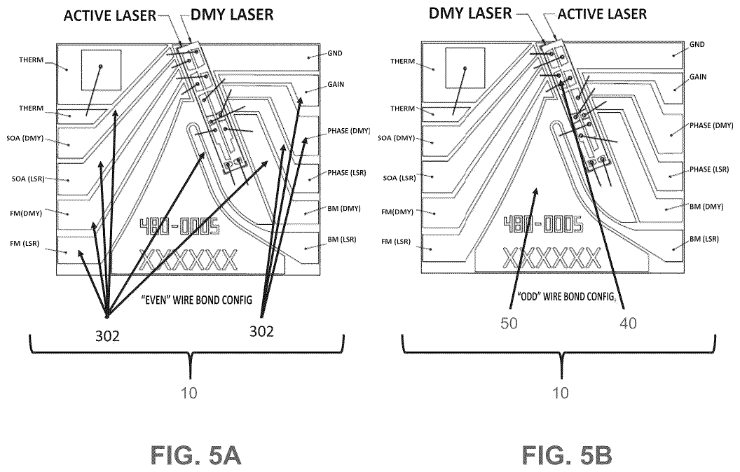

FIGS. 5A and 5B schematically illustrate two configurations of a chip 40 comprising two optoelectronic devices in accordance with certain embodiments described herein. The chip 40 (comprising, for example, III-V semiconductor material) is mounted on (e.g., soldered; epoxied; otherwise attached to) a carrier 50 (e.g., substrate) for thermal and mechanical stability. Either of the two optoelectronic devices on the chip 40 can be selected for optical connection to be used as the first optoelectronic device 100a (e.g., labeled “active laser” in FIGS. 5A and 5B) while the other of the two optoelectronic devices is selected to balance the thermal load to be used as the second optoelectronic device 100b (e.g., labeled “dmy laser” in FIGS. 5A and 5B). In certain embodiments, the selection is arbitrary, with the first optoelectronic device 100a interchangeable with the second optoelectronic device 100b. The two configurations of FIGS. 5A and 5B can be attained by using the same chip 40 and optoelectronic devices but with different connection configurations for the two configurations. For example, in the apparatus 10 of FIG. 5A, the left-most optoelectronic device on the chip 40 is wire bonded or otherwise connected to electrical ports 302 for the active device (e.g., first optoelectronic device 100a), and is subsequently optically connected to the optical system 22, while the right-most optoelectronic device on the chip 40 is wire bonded or otherwise connected to electrical ports for the compensation heat control (e.g., load-balancing) device and is not subsequently optically connected to the optical system 22. For another example, in the apparatus 10 of FIG. 5B, the right-most optoelectronic device on the chip 40 (e.g., first optoelectronic device 100a) is wire bonded or otherwise connected to electrical ports 302 for the active device, and is subsequently optically connected to the optical system 22, while the left-most optoelectronic device on the chip 40 is wire bonded or otherwise connected to electrical ports for the compensation heat control (e.g., load-balancing) device and is not subsequently optically connected to the optical system 22. In the configurations of FIGS. 5A and 5B, the roles of the two optoelectronic devices are switched relative to one another.

In certain embodiments, the electrical ports 302 are configured such that either of the configurations of FIGS. 5A and 5B can be readily implemented in the manufacturing process. In certain embodiments, one of the optoelectronic devices can have poor optical performance or not being optically functional (e.g., not being able to generate optical signals), but can still be electrically functional for generating heat for thermal compensation, and the selection of which of the configurations of FIGS. 5A and 5B is used can be based on a determination of which of the two optoelectronic devices has the preferred, better, best, etc., optical performance (e.g., such as higher or lower based on based on a selected metric such as: temporal variation of an intensity or power and/or wavelength of the optical signals generated by the optoelectronic device). In certain such embodiments, a higher yield of chips with thermal compensation is provided. In some examples, a better optical performance is an optical performance that is different from another optical performance by a threshold amount.

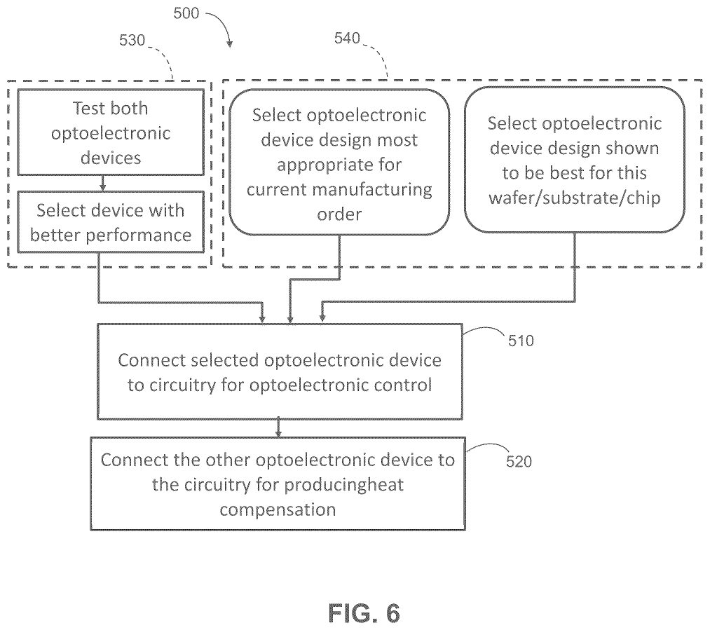

FIG. 6 is a flow diagram of an example method 500 in accordance with certain embodiments described herein.

In an operational block 510, the method 500 comprises connecting a first optoelectronic device 100a to electrical circuitry 30. The electrical circuitry 30 is configured to provide first electrical signals 32a to the first optoelectronic device 100a, the first electrical signals 32a configured to control optoelectronic operation of the first optoelectronic device 100a (e.g., to control the generation of optical signals 20a by the first optoelectronic device 100a). In an operational block 520, the method 500 further comprises connecting a second optoelectronic device 100b to the electrical circuitry 30. The electrical circuitry 30 is further configured to provide second electrical signals 32b to the second optoelectronic device 100b, the second electrical signals 32b configured to control heat compensation by the second optoelectronic device 100b. For example, the second electrical signals 32b can be configured to operate the second optoelectronic device 100b to generate a thermal load that is summed with a thermal load from the first optoelectronic device 100a such that a temperature of the first optoelectronic device 100a is controlled (e.g., substantially constant, with in a range) during operation of the first optoelectronic device 100a. In certain embodiments, the method 500 further comprises connecting an optical output port 20 of the first optoelectronic device 100a to an optical input port of an optical system 22 (e.g., via an optical coupler 24). In some examples, the optical output port may be connected to an optical connector (e.g., fiber optic connector) that is connected to optically coupled to the optical system. In some such examples the optical output port may be connected to an intermediary optical component (e.g., an optical adapter, a mode matching component and the like). In some other examples, the optical output port can be a facet or a mirror that couples light from the optoelectronic device to free space. In some such examples, the light coupled out by the output port may be coupled to an optical system using an intermediary optical system (e.g., comprising one or more one or more optical components such as lenses, polarizers, and the like).

In certain embodiments, method 500 comprises selecting one of two optoelectronic devices to use as the first optoelectronic device 100a. For example, in an operational block 530, the optical performance of both of the optoelectronic devices can be tested, and the optoelectronic device having the better, best, etc. optical performance (e.g., such as higher or lower based on a selected metric such as: temporal variation of an intensity or power and/or wavelength of the optical signals generated by the optoelectronic device) can be selected to use as the first optoelectronic device 100a. In some embodiments, testing the optoelectronic device may include but limited to: measuring the intensity or power of light output by the optoelectronic device as a function of one or more drive currents provided to the optoelectronic device, measuring the wavelength of light output by the optoelectronic device as a function of one or more drive currents provided to the optoelectronic device, measuring an optical modulation depth as a function of one or more modulating signals provided to optoelectronic device, monitoring the intensity or power of light output by the optoelectronic device over a period of time and the like. In some such embodiments, an optical performance of the optoelectronic device may be determined based at least in part on the measured intensity or power, measured optical modulation depth, variations in the intensity or power of measured light overtime and the like. In some examples, the testing procedure may comprise testing a first optical performance of the first optoelectronic device and a second optical performance of the second optoelectronic device. In some such examples, a better, best, etc. optical performance may comprise an optical performance that is different than another optical performance by a threshold amount.

In certain embodiments, the method 500 comprises selecting the first optoelectronic device 100a based on a design (e.g., the design most appropriate for the current manufacturing order and/or the design that is different than other designs on the same wafer/substrate/chip) of the first optoelectronic device in an operational block 540. In some examples, a design difference may be related to the size and shape of certain features of the device. For example, design differences between the first and second optoelectronic devices 100a, 100b can result in operational differences that make one device more useful for a particular application or operation of the apparatus 10 and the other device more useful for a different application or different operation. The determination of operational differences can be made after testing both the first and second optoelectronic devices 100a, 100b or can be based on the design differences, without testing both devices, where the design differences are known to result in operational differences or probabilities of operational differences. In some examples, the design difference can be a design of the fabricated device and can be associated with fabrication process. In some such examples, the design difference may be related to process variation from one wafer or substrate to another wafer or substrate. The device considered to be more useful for the particular operation of the apparatus 10 can be selected to be used as the first optoelectronic device 100a of the apparatus 10 while the other device considered to be more useful for a different application may be selected to be used as the second optoelectronic device 100b of the apparatus 10.

In some embodiments, once a first optoelectronic device is selected for generating optical signals, a second optoelectronic device is selected for producing heat compensation for the first optoelectronic device, and both optoelectronic devices are electrically connected to the electrical circuitry, the electrical circuitry may be configured, for example, by measuring temperatures of one or more sections of the first optoelectronic device. In some such embodiments, the electrical circuitry can be adjusted to provide electrical signals to the second optoelectronic device in order to maintain the measured temperature of one or more sections of the first optoelectronic device within a given temperature range while the first optoelectronic device is operational (e.g., generating optical signals, generating optical signals with varying intensity or power, generating optical signals with varying wavelengths and the like). In some examples, the temperature of one or more sections of the first optoelectronic device may be measured using one or more temperature sensors (e.g., thermistors, thermocouples, semiconductor temperature sensors or RTDs, and the like). In some such examples, the temperature sensors may be integrated with the first optoelectronic device. In some other examples, one or more temperature sensors may be temperature probes in thermal communication with one or more sections of the first optoelectronic device.

In some embodiments, once a first optoelectronic device is selected for generating optical signals, a second optoelectronic device is selected for producing heat compensation for the first optoelectronic device, and both optoelectronic devices are electrically connected to the electrical circuitry, the electrical circuitry may be configured, for example, by measuring the wavelength of the light generated by the first optoelectronic device. In some such embodiments, the electrical circuitry can be adjusted to provide electrical signals to the second optoelectronic device to enable tuning the measured wavelength within a given wavelength range. In some examples, enabling tuning the measured wavelength within a given wavelength range may comprise tuning the wavelength continuously within a wavelength range. In some examples, the wavelength of the optical signal generated by the first optoelectronic device may be measured using an optical spectrometer that is in optical communication with the first optoelectronic device (e.g., via an output port of the first optoelectronic device).

In some implementations, the second optoelectronic device 100b may be replaced by a device that is not capable of generating light. For example, an apparatus may comprise an optoelectronic device and a thermoelectric device (e.g., a resistive heater or a thermoelectric cooler) in thermal communication with the optoelectronic device. In such implementations, the apparatus may comprise one or more features described above with respect to the apparatus 10. In some cases, similar to the second optoelectronic device 100b described above, the thermoelectric device may provide heat compensation to adjust the temperature of at least a section of the optoelectronic device; however the thermoelectric device may not generate light. In some examples, the thermoelectric device may comprise one or more sections whose temperatures can be independently controlled. In some examples, an individual section of the thermoelectric device may be configured to provide thermal compensation to a corresponding section of the first optoelectronic device 100a. An electronic circuit or a controller (e.g., the electrical circuitry 30) may provide electrical currents (or voltages) to one or more sections of the thermoelectric device to controllably adjust the temperature of one or more sections of the first optoelectronic device 100a.

The heat compensating device may comprise, for example, a thermoelectric device such as a resistive heater comprising, for example, doped semiconductor such as a semiconductor junction, undoped or intrinsic semiconductor, metal such as low conductivity metal (e.g., tungsten). The resistive heater may include an input port for ingress of current and an output port for egress of current and/or for application of a voltage. Such components may be fabricated in or on a semiconductor substrate. The heat compensating device may also comprise other types of thermoelectric devices such as a thermoelectric cooler. In some cases, the resistive heater may comprise a film resistor (e.g., a thin film or a thick film resistor). In some examples, the resistive heater may comprise nichrome (NiCr) or other alloys. In some cases, the compensating device may comprise a semiconductor or a semiconductor junction.

### Calibration of Heat Compensating Device

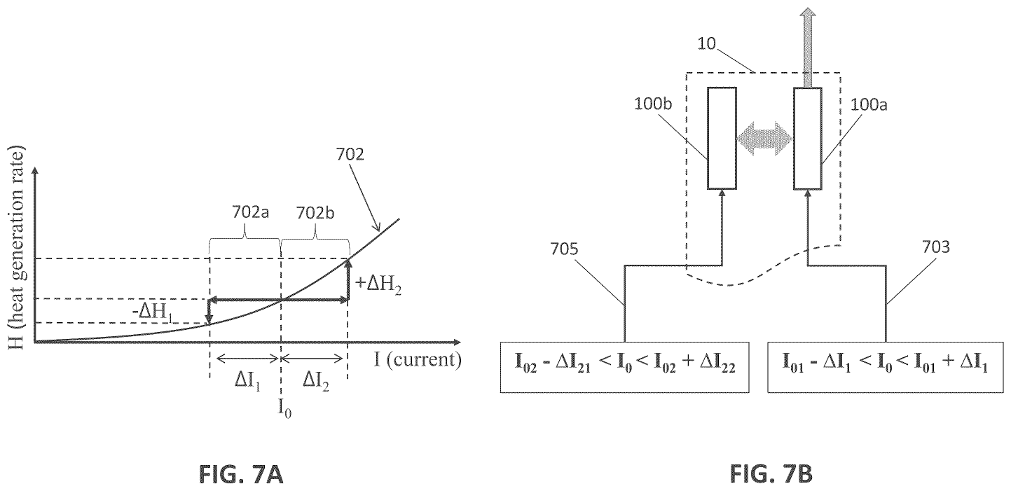

FIG. 7A schematically illustrates heat dissipation rate (dissipated thermal power) by an optoelectronic device, e.g., optoelectronic device 100a or 100b in apparatus 10 shown in FIG. 7B, or a thermoelectric device, as a function of the electrical current (I) provided to the optoelectronic device. The apparatus 10 and the optoelectronic devices 100a or 100b in FIG. 7B may comprise one of more features described above with respect to the apparatus 10 and the optoelectronic devices 100a or 100b in FIGS. 1A, 1B, 2A and 2B. As described above with respect to FIGS. 1A and 1B and shown in FIG. 7B, in some cases, an apparatus 10 may comprise a first optoelectronic device 100a optically connected to an output port 20 and a second optoelectronic device 100b in thermal communication with the first optoelectronic device 100a, and is configured to control (e.g., stabilize, reduce fluctuation, etc.) the temperature of one or more sections of the first optoelectronic device 100a. With reference to FIGS. 1A and 1B, in some cases, the electrical signals 32a may be provided to the first optoelectronic device 100a to alter or control a characteristic of light generated by the first optoelectronic device 100a. For example, the electrical signals 32a may comprise a first electrical current 703 applied to one or more sections of the first optoelectronic device 100a, and the first electric current 703 may be modulated to generate a modulated output beam of light (e.g., amplitude modulated). In some other cases, the first electrical current 703 applied to one or more sections of the first optoelectronic device 100a may be modulated or changed to modulate, change, or sweep, a wavelength of light output by the first optoelectronic device 100a. In some cases, changing or modulating the first electrical current provided 703 to a section the first optoelectronic device 100a induces a temperature change in that section and potentially other sections of the first optoelectronic device 100a. To reduce or potentially eliminate such temperature change, which can affect the operation of the first optoelectronic device 100a, the second electrical signals 32b provided to the first optoelectronic device 100a may be adjusted. In some cases, the second electrical signals 32b may comprise a second electrical current 705 provided to one or more sections of the second optoelectronic device 100b. The second electrical current 705 may be adjusted or modulated to reduce the temperature change in one or more sections of the first optoelectronic 100a by providing thermal compensation. For example, when a first electrical current 703 provided to a first section of the first optoelectronic device 100a increases, a second electrical current provided to a second section of the second optoelectronic device 100b may be decreased to lower a temperature of second section with respect to the first section so at least a portion of heat generated in the first section flows to the second section. Similarly, when the first electrical current 703 provided to a first section of the first optoelectronic device 100a decreases, a second electrical current 705 provided to a second section of the second optoelectronic device 100b may be increased to increase the temperature of second section with respect to the first section and to cause so heat flow from the second section to the first section. As a result, when the first electrical current 703 is modulated or changed, the second electrical current 705 can stabilize the temperature of the first section by controlling the rate and direction of the thermal energy exchange between the first and the second sections.

As shown in FIG. 7A, the heat dissipation rate (H) by the optoelectronic device (or thermoelectric device) can be a nonlinear function of the current applied to the device (e.g., to a section of the optoelectronic device). In some examples, the heat dissipation rate can be expressed as I²×R, where R can be a resistance or effective resistance of the optoelectronic device or a resistance of a section of the optoelectronic device to which the electrical current is provided. In some cases, the electric current provided to an optoelectronic device may comprise a time varying electrical current configured to modulate optical power generated by a functional optoelectronic device configured to generate light (e.g., the first optoelectronic device 100a), or the electric current provided to a heat compensating electronic device (e.g., the second optoelectronic device 100b) to offset or balance heat generation by the functional optoclectronic device and stabilize its temperature. In some examples, the time varying current may change (e.g., oscillate) between I₀−|ΔI₁| and I₀+|ΔI₂|, where I₀ is a bias current (also referred to as a bias point) and ΔI₁ and ΔI₂ are positive and negative electric current variation magnitudes with respect to the bias current. In some cases, |ΔI₁| can be equal or substantially equal to |ΔI₂|. Due to the nonlinearity of the heat dissipation process, for a given bias current I₀, a change in heat dissipation rate can depend on whether the electric current increases or decreases. Given the nonlinear dependence of heat dissipation on the current provided to a device or a section of a device (as shown in FIG. 7A), to stabilize the temperature of the first section, a magnitude of the second electrical current 705 provided to the second optoelectronic device may be adjusted not only based on the amplitude of the change made to the first electrical current 703 but also based on a first bias current (I₀₁) around which the first electrical current is changed or modulated.

FIG. 7A shows when |ΔI₁|=|ΔI₂|=ΔI, an increase in heat generation rate (ΔH₂) in response to changing the electrical current from I₀ to I₀+ΔI can be different from (e.g., larger than) a reduction of the heat generation rate (ΔH₁) in response to changing the current from I₀ to I₀−ΔI. The difference between ΔH₁ and ΔH₂ is caused by a difference between the slope (or an average slope) of a first portion 702a of the curve 702 corresponding to I<I₀ and/or ΔI₁<0, and the slope of a second portion 702b of the curve 702 corresponding to I>I₀ and/or ΔI₂>0. As such, in some cases, the electric current provided to the heat compensating device may be modulated or adjusted asymmetrically with respect to a bias current in order to increase and decrease the amount of heat generated by the heat compensating device by the same amount or magnitude. More generally, a signal provided to the heat compensating device may be adjusted or modulated non-symmetrically with respect to a bias point and according to a heat generation characteristic and thereby a current-voltage characteristic of the heat compensating device. In some cases, a resistance (e.g., a current or voltage dependent effective resistance) of the heat compensating device may be determined using a measured current-voltage characteristic of the heat compensating device and the resistance may be used to determine the dependence of heat generation rate (H) as a function of electric current (or voltage) provided to the heat compensating device. Next a bias point (e.g., bias current) is selected and a variation (e.g., an asymmetric variation) of the current provided to the heat compensating device with respect to bias point may be determined based on the determined relation between heat generation and electric current.

With reference to FIG. 7B, in some examples, the first and second optoelectronic devices 100a, 100b, can be substantially identical devices with identical or substantially similar dimensions and/or current-voltage (IV) characteristics. In some cases, for example, the dimensions may be different by no more than 20%, 15%, 10%, 5%, 1%, 0.5%, 0.1% or any range formed by any of these values or possible larger or smaller. In some cases, the the first and second optoelectronic devices 100a, 100b, may receive identical or substantially identical bias currents (I₀) during the operation of apparatus 10. In some examples, the first optoelectronic device 100a may comprise a first optical cavity formed between a first front mirror and a first back mirror, and the second optoelectronic device 100b may comprise a second optical cavity formed between a second front mirror and a second back mirror, wherein dimensions of the first optical cavity. In some cases, the first front mirror, and the first back mirror are identical to those of the second optical cavity, the second front mirror, and the second back mirror or the dimensions may be different by no more than 20%, 15%, 10%, 5%, 1%, 0.5%, 0.1% or any range formed by any of these values or possible larger or smaller. The optical cavity may comprise a first gain section and/or a first phase section, and the second optical cavity may comprise a second gain section and/or a second phase section. In some cases the dimensions (e.g., a thickness, a length, a width, or any combination thereof) of the first phase section and the first gain section can be identical to those of the second phase section and the second gain section or the dimensions may be different by no more than 20%, 15%, 10%, 5%, 1%, 0.5%, 0.1% or any range formed by any of these values or possible larger or smaller.

In these examples, the temperature variations generated by modulating the first electrical current 703 provided to the first optoelectronic device 100a, around I₀, may not efficiently be compensated by providing a second electrical current 705 having an opposite sign but otherwise equal to the first electrical current 703, to the second optoelectronic device 100b. Given the nonlinearity of heat generation rate with respect to current, providing a second electrical current 705 that is just a phase shifted copy of the first electric current (e.g., by 180 degrees), to the second optoelectronic device 100b, may not result in temporal variation of heat dissipation shown in FIG. 4 where the combined average heat from the two sections remains constant. As such, to balance the heat generated by the first optoelectronic device 100a, the second electrical current 705 provided to the second optoelectronic device 100b may be adjusted taking into account the nonlinearity of heat generation rate with respect to the second electric current 705.

In some implementations, the electrical circuitry 30 that provides the first and second electrical signals 32a, 32b, to the first and second optoelectronic devices 100a, 100b, may be configured to adjust the second electrical signals 32b, based at least in part on the first electrical signals 32a. In some examples, the electrical circuitry 30 may adjust a property or characteristic of the second electrical current 705 based on a property or characteristic of the first electrical current 703. The property or the characteristic may include a rate of change, a peak value, a phase, an amplitude, and the like. For example, an amplitude of the second electrical current 705 may be changed before the first electrical current 703 is changed, and with a rate larger than those of the first electrical current 703, by a specified amount, where a time difference between the respective changes is also specified. In some cases, the electrical circuitry 30 may adjust the second electrical current 705 based on the first electrical signals 32a (e.g., the current 703, a voltage, etc.), taking into account the nonlinearity of heat generation rate by the second optoelectronic device 100b with respect to the second electrical current 705. In some implementations, the first and the second optoelectronic devices 100a, 100b, may have different designs, dimensions, structural characteristics, and/or material properties. In some other implementations, the second optoelectronic device 100b may be replaced by a thermoelectric device that is not capable of generating light. In these implementations, a bias or average value of the second electrical current 705 can be different from those of the first electrical current 703, however still the second electrical current 705 may be adjusted based at least in part on the nonlinear dependence of heat generation rate by the thermoelectric device on the second electrical current 705.

In various implementations, the second electrical signals 32b (e.g., the second electrical current 705) can be configured to operate the second optoelectronic device 100b (or a thermoelectric device in thermal communication with the first optoelectronic device 100a), such that a temperature or an average temperature of the first optoelectronic device 100a or at least a section of the first optoelectronic device 100a, does not change more than 1%, 3%, 5%, or 10%. In some examples, when the first electrical signals 32a are periodic, the average temperature can be determined over one or more periods of the first electrical signals 32a. In some other examples, the average temperature may be determined over a time period during which the first electrical signals 32a are adjusted to control, change, modulate, or sweep a characteristic of light generated by the first optoelectronic device 100a.

In some examples, the current-voltage (IV) characteristics of the first and the second optoelectronic devices 100a, 100b (or a thermoelectric device used for thermal compensation), may be individually measured to fully characterize their heat generation rate as a function of the electrical current received.

In some cases, the measured IV curve of an optoelectronic device (or a thermo-electric device) may be used to determine a resistance (R) of the optoelectronic device (or the thermo-electric device) as a function of voltage (or current) applied to the device. For example, a voltage (V) applied to the optoelectronic device (or the thermoelectric device) may be varied within a given range and a current (I) passing through the optoelectronic device (or the thermoelectric device) may be measured at different voltage values to calculate R=V/I for different values or V and corresponding I. In some cases, the resistive heat generation rate or thermal power generated by the optoelectronic device may be estimated as I²×R based on measured variation of R as a function of I. In some cases, where the device comprises a pn junction, the resistive heat generation rate or thermal power generated by the optoelectronic device may be estimated as I²×R+V_{d}×I based on measured variation of R as a function of I, where V_{d} is the diode voltage of the pn junction.

Once R and/or heat generation rate of a light generating optoelectronic device and/or the corresponding heat compensating optoelectronic (or thermoelectric) device are fully characterized, the second electrical current 705 provided to the heat compensating optoelectronic device 100b (or electronic device), can be determined based on a first electrical current 703 provided to the first optoelectronic device 100a and the measured heat generation characteristics (e.g., R) for both devices. In some cases, an electronic circuit or control system (e.g., the electrical circuitry 30) that adjusts the electrical currents provided to the optoelectronic devices of apparatus 10 may be calibrated and/or programmed to determine and provide the second electrical current 705 to the second (heat compensating) optoelectronic device 100b based on a current provided to the first optoelectronic device and resistive or heat generation characteristics of the first and/or the second optoelectronic devices 100a, 100b.

In some examples, the current-voltage (IV) characteristics of individual sections of the first and/or the second optoelectronic devices 100a, 100b (or a thermoelectric device used for thermal compensation), may be measured separately to fully characterize the heat generation characteristics (e.g., heat generation rate or R) as a function of the electrical current provided to these sections. In some cases, an individual section of an optoelectronic device (e.g., the first optoelectronic device 100a), may include a phase section, an optical amplifier section, optical gain section, a mirror, an optical absorber, or the like.

In some cases, the measured heat generation and/or resistive characteristics of the first and the second optoelectronic devices 100a. 100b, may be stored in a non-transitory memory of a control system (e.g., the electrical circuitry 30) and used by a control algorithm (e.g., current control algorithm) executed by the control system.

In some examples, an electrical circuitry (e.g., electric circuitry 30) that provides a second electric current 705 to a heat compensating device (e.g., the second optoelectronic device 100b) may be configured to adjust a signal property of the electrical signal provided to the heat compensating device non-symmetrically based at least in part on the current-voltage characteristic of the heat compensating device. In some examples, the electrical circuitry may adjust a signal property of the second electrical signal non-symmetrically with respect to a bias point in a manner consistent with a nonlinearity of a resistance or a current of the heat compensating device, or a nonlinearity in a heat generation rate of the heat compensating device.

### Temporal Current Control for Fast and Stable Heat Compensation

The heat transfer between the second optoelectronic device 100b (or an electronic heat compensating device), is not instant; as a result, there can be delay between changing the second electrical current 705 provided to the second optoelectronic device 100b and its impact on the temperature of one or more sections of the first optoelectronic device 100a. For example, when the first electrical signals 32a (e.g., the first electrical current 703), provided to one or more sections of the first optoelectronic device 100a are increased (or decreased) starting as a time tₛ, decreasing (or increasing) the second electrical current 705 provided to the second optoelectronic device 100b (e.g., to a corresponding section of the second optoelectronic device 100b) at the same time tₛ may not keep the temperature of the corresponding sections of the first optoelectronic device 100a substantially constant or within a desired range at least during a delay (or thermal response) period tₛ−tᵣ, where tᵣ is the time at which the change made to the second electrical current 705 thermally affects the first optoelectronic device 100a. In some cases, a change in the temperature of one or more sections of the optoclectronic device 100a can be nonlinear with respect to a change in the second current 705. In some cases, a change in the rate of heat transfer rate between the optoelectronic device 100a and the optoelectronic device 100b (or another heat compensating device) can be nonlinear with respect to a change in the second current 705.

In some implementations, the electrical circuitry 30 may control the first electrical current 703 (or one of the first signals 32a) and the second electrical current 705 such that a time (t₂) at which the second electrical current 705 is changed, lags behind or leads the time t₁ at which the first electrical current 703 undergoes a change or discontinuity. In some cases, the change or the discontinuity of the first electrical current 703 can be associated to a rate of change larger than a threshold value. In various implementations, |t₁−t₂| can be from 10 to 20 nanoseconds, 20 to 100 nanoseconds, from 100 nanoseconds to 1 microsecond, from 1 to 100 microseconds, from 100 microseconds to 1 millisecond, from 1 to 10 milliseconds or any range formed by these values or larger or smaller values. In some cases, |t₁−t₂| may be determined based on the geometries of the first and second optoelectronic devices 100a/100b, a rate of change of the first electric current 703, and/or a period (or frequency) of the first electrical current 703, or any combination of these parameters.

Additionally or alternatively, in some implementations, the electrical circuitry 30 may control the second electrical current 705 such that an initial slope (rate of change) of the second electrical current 705 is sufficiently large to reduce or maintain a delay between the change made to the second electrical current 705 and the resulting change in the temperature of at least a section of the first optoelectronic device 100a, below a threshold delay value. In some cases, the threshold delay value can be from 10 to 20 nanoseconds, 20 to 100 nanoseconds, from 100 nanoseconds to 1 microsecond, from 1 to 100 microseconds, from 100 microseconds to 1 millisecond, from 1 to 10 milliseconds or any range formed by these values or larger or smaller values. In some cases, the threshold delay may be determined based on the geometries of the first and second optoelectronic devices 100a/100b, a rate of change of the first electrical current 703, or a period (or frequency) of the first electrical current 703, or any combination of these parameters.

In some cases, the second electrical current 705 provided to the second optoelectronic device 100b device may be pre-emphasized or post-emphasized with respect to a change made to the first electrical signals 32a to increase a rate of heat transfer between the first and the second optoelectronic devices 100a and 100b and thereby the speed by which a thermal equilibrium is reached between the first and the second optoelectronic devices 100a and 100b, or the temperature of the first optoelectronic device 100a is stabilized. In various implementations, a pre-emphasized or post-emphasized current may include a deviation of timing, magnitude, temporal behavior, or any combination of these, of the second electrical current 705, from a timing, magnitude, or temporal behavior of the first electrical current 703. In some cases, a pre-emphasized or post-emphasized current may include a deviation of timing, magnitude, temporal behavior, or any combination of these, of the second electrical current 705, from a monotonous (e.g., linear) change from an initial value to a final value.

In some cases, variations of a stabilized temperature may not exceed a temperature uncertainty limit. In some cases, the temperature uncertainty limit can be an upper bound for temperature fluctuations (or variations) of the light generating optoelectronic device (e.g., the first optoelectronic device 100a) or a section of the light generating optoelectronic device. In various implementations, the temperature uncertainty limit can be from 0.0001 to 0.0005 degrees, from 0.0005 to 0.001 degrees, from 0.001 to 0.005 degrees, from 0.005 to 0.01 degrees, from 0.01 to 0.05 degrees, from 0.05 to 0.1 degrees, or any range formed by these values or larger or smaller values. The temperature uncertainty limit for an optoelectronic device or an apparatus may comprise a specified value or range determined based on an application of the optoelectronic device or the apparatus. For example, when light generated by the optoelectronic device is provided to another optical system or device, the temperature uncertainty limit for the optoelectronic device may be determined based on sensitivity of the other optical device or the optical system on wavelength and/or power of light received from the optoelectronic device. In some cases, a temperature uncertainty limit may be determined based on a specified wavelength uncertainty limit for an application. In some examples, the specified wavelength uncertainty limit can be smaller than 10⁻⁷, smaller than 10⁻⁶, smaller than 10⁻⁴, or smaller than 1% of a wavelength (e.g., a center wavelength) of light generated by the optoelectronic device.

In some cases, a signal provided to one or more sections of the second optoelectronic device 100b (the heat compensating device) may be adjusted such that the temperature of one or more sections of the first optoelectronic device 100a remain within ±0.0001, ±0.001%, ±0.01%, ±0.1%±1%, ±2%, ±3%, ±4%, ±5%, ±6%, ±7%, ±8%, ±10%, or ±20% of a specified temperature, or any range between any of these values.

In some cases, a signal provided to one or more sections of the second optoelectronic device 100b (the heat compensating device) may be adjusted such that the temperature of one or more sections of the first optoelectronic device 100a remain within ±10⁻⁶° C., ±10⁻⁵° C., ±10⁻⁴° C., ±10⁻³° C., ±10⁻²° C., or ±10⁻¹° C., or any range between any of these values, from a specified temperature.

In some cases, a signal provided to one or more sections of the second optoelectronic device 100b (the heat compensating device) may be adjusted to stabilize the wavelength (e.g., center wavelength) of light generated by the first optoelectronic device near a target wavelength. In some cases, the target wavelength can be a time dependent and temporally change according to a predefined temporal profile. In some cases, stabilizing or tuning the wavelength (e.g., center wavelength) of light generated by the first optoelectronic device comprises maintaining the wavelength within ±0.00001%, within ±0.0001%, within ±0.001%, within ±0.01%, within ±0.1%, within ±1%, within ±2%, within ±3%, within ±4%, within ±5% of the target wavelength, or any range between any of these values. In some cases, stabilizing or tuning the wavelength (e.g., center wavelength) of light generated by the first optoelectronic device comprises maintaining the wavelength within ±10⁻² picometer, within ±10⁻¹ picometer, within ±1 picometer, within ±10 picometers, within ±100 picometers, within ±1 nanometer from a target wavelength or any range between any of these values. In some cases, the target wavelength may comprise wavelengths around 850 nm, 980 nm, 1300 nm, or 1550 nm.

With continued reference to FIG. 7B, in some cases, when a change is made to the second electrical current 705 in response to a change in the first electrical current 703, an amplitude of a pre-emphasized (or post emphasized) second electrical current 705 may comprise a local maximum or a local minimum, following the change made to the second electrical current 705. The local maximum may comprise an overshoot and the local minimum may comprise an undershoot with respect to the first electrical current 703. For example, a pre-emphasized (or post emphasized) second electrical current 705 may comprise an increase or decrease such as a progressive increase or decrease or a monotonic increase or decrease or growth (e.g., linear growth) from an initial value followed by a local maximum and a decay to a later value. A pre-emphasized second electrical current 705 may comprise a local maximum (or local minimum) prior to a variation of the first electrical current 703, and post-emphasized second electrical current 705 may comprise a local maximum (or local minimum) after a variation of the first electrical current 703 (or first signals 32a).

In various implementations, a delay between the local maximum (or local minimum) of the second electrical current 705 and a local maximum (or local minimum) of the first electrical current 703 can be from 1 to 10 nanoseconds, from 10 to 100 nanoseconds, from 100 nanoseconds to 1 microseconds, from 1 to 10 microseconds, from 10 to 1 milliseconds, or any range formed by these values or larger or smaller values.

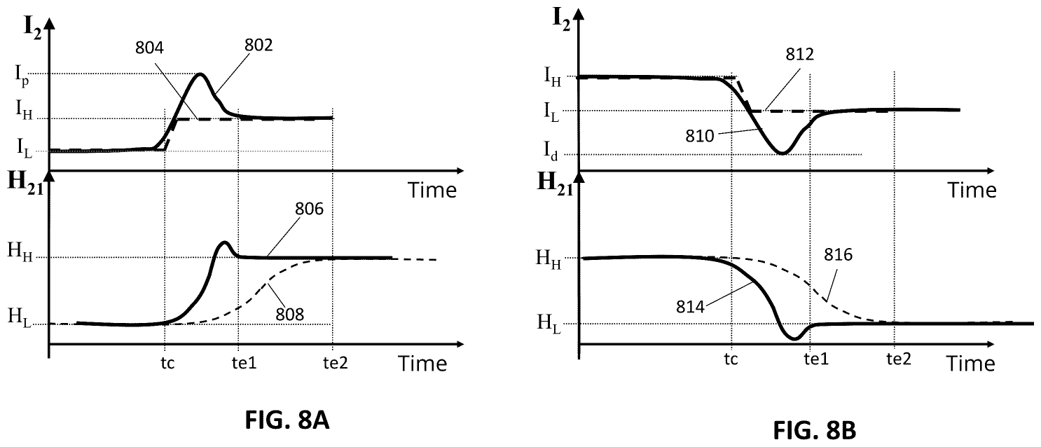

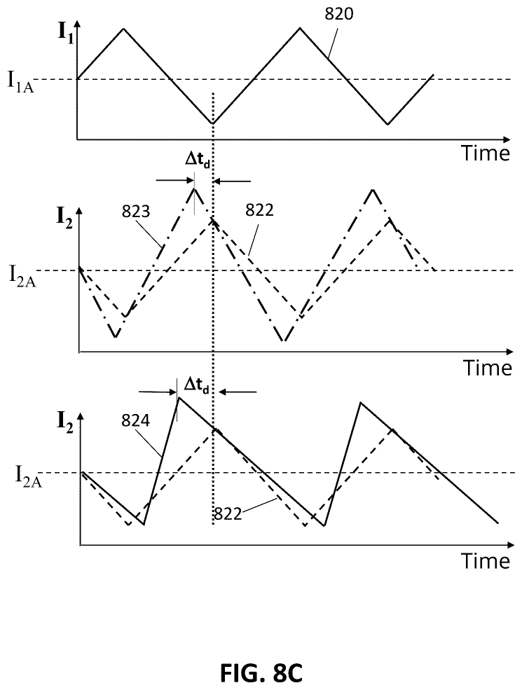

FIGS. 8A-8B schematically illustrate two example temporal variations of the electrical current (I₂) 802, 804, provided to a heat compensating device (e.g., the second optoelectronic device 100b) and the resulting changes in the heat transfer rate (H₂₁) 806, 808, from the heat compensating device to a light generating optoelectronic device (e.g., the first optoelectronic device 100a). In some cases, the electrical current 804 can be a modified electrical current with respect to the electrical current 802 and results in faster thermal control of the light generating optoelectronic device. FIGS. 8A and 8B respectively show, (A) the electrical current is increased to provide heat to the light generating optoelectronic device and (B) the electrical current is reduced to absorb heat from the light generating optoelectronic device. The solid and dashed lines represent heat transfer rate variations and the respective electrical currents corresponding to faster and delayed thermal control respectively.

In the example shown in FIG. 8A it is assumed that the temperature of at least a section of an optoelectronic device (e.g., the first optoelectronic device 100a) is decreasing so thermal energy flows from the heat compensating device to the optoelectronic device. As such the electrical current I₂ (e.g., the second electrical current 705) is increased from a lower initial value I_{L} to a higher final value I_{H}, e.g., to establish or increase heat flow (H₂₁) from the heat compensating device (e.g., the second optoelectronic device 110b) to the corresponding section of the optoelectronic device. As a result, the rate of thermal energy transfer (H₂₁) from the heat compensating device to the optoelectronic device increases from a lower value H_{L}, corresponding to an initial thermal equilibrium, to a higher value H_{H} corresponding to a new thermal equilibrium between the heat compensating device and the optoelectronic device. In the example shown, the modified electrical current I₂ 802 (solid line) includes an overshoot when transitioning from the lower value IL to the higher value I_{H}, while the electrical current I₂ 804 increases monotonously (e.g., linearly) from the lower value I_{L} to the higher value I_{H}. In some examples, a difference between a peak value (Iₚ) of the modified electrical current I₂ 802 and the lower value I_{L} can be larger than a difference between the higher value I_{H} and the lower value I_{L}, by a factor from 1.2 to 1.5, 1.5 to 2, 2 to 4, 4 to 6, 6 to 8, 8 to 10, 10 to 50, or any range formed by these values or larger or smaller values. The thermal energy transfer (H₂₁) 806 resulting from the modified electrical current I₂ 802 changes from the lower value H_{L} to the higher value H_{H} in a time period (tₑ-tₑ₁), which is shorter than a time period (tₑ₂-tₑ) required for the thermal energy transfer (H₂₁) 808, resulting from the electrical current I₂ 804, to change from the lower value H_{L} to the higher value H_{H}.

As shown in the bottom panel, the modified electrical current I₂ 802 (solid line), can stabilize thermal energy transfer (H₂₁) 806, and thereby the temperature of the optoelectronic device, faster than the electrical current I₂ 804 (dashed line). In some cases, an overshoot of the second electrical current may result in an overall faster temperature compensation without causing an overshoot of the first electrical current.

In the example shown in FIG. 8B it is assumed that the temperature of at least a section of an optoelectronic device (e.g., the first optoelectronic device 100a) is increasing so thermal energy has to flow from the optoelectronic device to the heat compensating device. As such, the electrical current I₂ (e.g., the second electrical current 705) is decreased from a higher value I_{H} to a lower value I_{L} to decrease heat flow (H₂₁) from the heat compensating device to the corresponding section of the optoelectronic device. As such, the rate of thermal energy transfer (H₂₁) from the heat compensating device to the optoelectronic device is decreased from an initial higher value H_{H}, corresponding to an initial thermal equilibrium, to a final lower value H_{L}, corresponding to a new thermal equilibrium between the heat compensating device and the optoelectronic device. The electrical current I₂ 810 (solid line), that includes an undershoot between the higher and lower values I_{H} and I_{L}, can stabilize the temperature of the optoelectronic device faster than the electrical current I₂ 812 (dashed line), that is decreases monotonously (e.g., linearly) from the higher I_{H} value to the lower value I_{L}. In some examples, the absolute value of a difference between a minimum (I_{d}) of the modified electrical current I₂ 810 and the lower value I_{L} can be larger than a difference between the higher value I_{H} and the lower value I_{L}, by a factor from 1.2 to 1.5, 1.5 to 2, 2 to 4, 4 to 6, 6 to 8, 8 to 10, 10 to 50, or any range formed by these values or larger or smaller values.

FIGS. 8A and 8B show that while both electrical currents 802, 804 (or 812 and 810) are changed substantially at the same time (tₑ), the overshoot (or undershoot) in the electrical current 802 (or 810) causes the heat transfer rate to reach the final value H_{H} (or H_{L}) faster and thereby stabilizes the temperature of the optoelectronic device in a shorter period. In some examples, the delay between the time tₑ₂ and tₑ₁ at which the new thermal equilibrium is established by the electrical current 802 (or 810) and the electrical current 804 (or 802) respectively, may depend on the magnitude of the local maximum Iₚ (or local minimum I_{d}) of the electrical current 802 (or 810) and the slopes of the electrical current 804 (812) and the electrical current 802 (810) during a growth or decay period. In some cases, the time tₑ at which a change to I₂ 705 is initiated may be determined based on a time at which a change is made to the first electrical current 703. For example, tₑ can be before the time at which the change is made to the first electrical current 703.

FIG. 8C shows an example temporal variation of the electric current I₁ 820 (e.g., electric current 703) provided to a section of the first optoelectronic device 100a and two example temporal variations of a modified electric current (I₂) 823, 824 (e.g., electric current 705) provided to a section of the second optoelectronic device 100b (e.g., the heat compensating device) to stabilize the temperature of the first optoelectronic device 100a. In some cases, the modified electric current (I₂) 823, 824, can be a pre-emphasized electric current. In the example shown electric current I₁ 820 comprises a periodic triangular wave having identical (or nearly identical) positive and negative slopes and a symmetric amplitude variation with respect to an average electric current I_{1A}. In some cases, an electric current I₂ 822 (dashed line) that is 180 degrees phase shifted with respect to the current I₁ 820 but has a temporal variation substantially identical to that of the electric current I₁ 820, may be provided to the second optoelectronic device 100b, to stabilize the temperature of the first optoelectronic device 100a. In some examples, where the first and the second optoelectronic devices are substantially identical devices, the electrical current I₁ 820 and I₂ 822 can have substantially equal amplitudes. In some cases, the electric current I₂ 822 may not compensate for the temperature variation of the first optoelectronic device 100a with sufficient speed and/or efficiency and result in residual temperature variations of the first optoelectronic device 100a. In some implementations, providing a modified electric current (e.g., a pre-emphasized electric current) I₂ may improve the heat compensation speed and efficiency and thereby reduce the residual temperature variations of the first optoelectronic device 100a. In some examples, a modified electric current I₂ 823 can be a pre-emphasized electric current I₂ 823 (dashed-dotted line) that has a temporal profile substantially similar to that of the electric current I₂ 822 but a local maximum of the pre-emphasized electric current 823 is delayed (Ata) relative to a respective local maximum of the electric current I₂ 822. In some such examples, a pre-emphasized electric current I₂ 823 may have a larger amplitude than the electric current I₂ 822. In some examples, a modified electric current I₂ can have a different temporal profile compared to the electric current I₂ 822. For examples, with reference to electric current I₂ 822, a modified electric current I₂ can be a pre-emphasized electric current I₂ 824 (solid line) having an asymmetric (e.g., saw tooth) temporal profile that is delayed with respect to the electric current I₂ 822.

In various implementations, the delay (Ata) between a peak of the pre-emphasized electric current I₂ 823 (or 824) and a corresponding dip (local minimum) and/or onset of stead state of the electric current I1 820 can be from 1 to 10 nanoseconds, from 10 to 100 nanoseconds, from 100 nanoseconds to 1 microseconds, from 1 to 10 microseconds, from 10 to 1 milliseconds, or any range formed by these values or larger or smaller values.

In some cases, the absolute value of a local maximum of the electrical signal (e.g., the modified electric current I₂ 823, 824, or electric current 705) provided to a section of the heat compensating device (e.g., the second optoelectronic device 100b), can be larger than the absolute value of the local minimum of the electrical signal (e.g., electric current I₁ 820 or electric current 703) provided to the light generating optoelectronic device (e.g., the first optoelectronic device 100a).

In some cases, the absolute value of a local minimum of the electrical signal (e.g., the modified electric current I₂ 823, 824, or electric current 705) provided to a section of the heat compensating device (e.g., the second optoelectronic device 100b), can be larger than the absolute value of the local maximum of the electrical signal (e.g., electric current I₁ 820 or electric current 703) provided to the light generating optoelectronic device (e.g., the first optoelectronic device 100a).

In some cases, during a transitionary period when the second electrical current 705 provided to the heat compensating device is changed from a lower value to higher value (from a higher value to a lower value), the second electrical current 705 may be distorted compared to the first electrical current 703, to increase a speed by which a thermal equilibrium is reached between the first and the second optoelectronic devices 100a and 100b, or the temperature of the first optoelectronic device 100a is stabilized. The distortion may include any linear, nonlinear, discontinuous, stepwise behavior different from a continues and monotonous change from an initial value to a final value. In some examples, the distorted second electrical current 705 may increase such speed by increasing a rate of heat transfer between the first and the second optoelectronic devices 100a and 100b.

In some cases, the transitionary period may overlap, precede, or succeed a period during which the first electrical signals 32a (e.g., the electrical current 703) are changed. A distorted current may comprise one or more inflection points, one or more local maximums, one or more local minimums, or other features.

The characteristics of a pre or post emphasized electrical current, or signal provided to the heat compensating device may be determined based on a response time quantifying a delay between a change made to the second current 705 provided to the heat compensating device (e.g., the second optoelectronic device 100b) and the resulting temperature change in the optoelectronic device (e.g., the first optoelectronic device 100a).

The response time may depend on structural and geometrical properties of the optoelectronic and the heat compensating device, the substrate (or chip) on which these devices are fabricated, a distance between the two devices and the like. For example, the response time may depend on the thickness of the substrate, location of a p-type layer (p-side) of one or both devices with respect to the substrate (e.g., p-side down or p-side up mounted), a lateral distance between the two devices, electrical and thermal impedances of the devices, thermal mass of electrical contacts used to provide signals (e.g., currents) to these devices, and the like.

In some implementations, the characteristics of a signal provided to a heat compensating device and its timing with respect to a change made to a signal provided to the optoelectronic device thermally controlled by the heat compensating device, may be determined using a calibration process. Subsequently an electrical circuitry that controls the signals provided to these devices can be adjusted, programed and/or configured according to the determined characteristics. In some cases, the calibration process may comprise changing a first signal provided to the optoelectronic device and adjusting a second signal provided to the heat compensating device while monitoring the wavelength of light generated by the optoelectronic device. In some cases, the wavelength of the optoelectronic device may be monitored using a wave meter, an oscilloscope, a system comprising an etalon, a grating, a Mach-Zehnder interferometer, or other frequency/wavelength selective devices and one or more photodetectors (e.g., photodiodes) configured to generate detection signals upon receiving optical power. In some cases, a wavelength selective optical device may comprise an optical interferometer or an optical filter.

In some cases, adjusting the second signal may comprise, pre-emphasizing, post-emphasizing, or otherwise distorting the second signal during a transitionary period. Additionally, adjusting the second signal may comprise adjusting a temporal alignment between the transitionary period and a period during which the first signal is changed. Changing the first signal may comprise modulating the amplitude of a current or voltage provided to at least a section of the optoelectronic device. In some examples, the second signal may be adjusted to maintain the wavelength of light generated by the optoelectronic device substantially constant or within a wavelength uncertainty limit centered at a target wavelength. In some cases, wavelength uncertainty limit can be less than 10⁻⁷, less than 10⁻⁶, less than 10⁻⁵, less than 10⁻⁴, less than 10⁻³, less than 1%, less than 5%, or less than 10%, times the wavelength (e.g., a center wavelength) of light generated by the optoelectronic device (e.g., the first optoelectronic device 100a). In some cases, wavelength uncertainty limit can be from 10⁻² picometers to 10⁻¹ picometers, from 10⁻¹ picometers to 1 picometers, from 1 picometer to 10 picometers, from 10 picometers to 100 picometers or any range formed by these values or larger or smaller values.

In some examples, the second signal may be adjusted to maintain the optical power of light generated by the optoelectronic device substantially constant or within a power uncertainty limit. In some cases, the power uncertainty limit can be less than 10⁻⁵, 10⁻⁴, less than 10⁻³, less than 1%, less than 5%, or less than 10%, times a target optical power.

In some examples, the second signal may be adjusted to increase a speed of thermal control (e.g., reducing the response time), or improve the stability of temperature of the optoelectronic device.

In some implementations, the thermal control of a section of the optoelectronic device may be affected by a thermal response time of the corresponding heat compensating device (e.g., an optoelectronic device or a thermoelectric device). As such in these implementations, the amplitude of the electric current provided to the heat compensating device, and its temporal alignment with respect to an electric current provided to the optoelectronic device may be determined based at least in part on the response time of the heat compensating device.

In some implementations, the electrical circuitry 30 may be programed or configured to provide or tailor a temporal profile and/or amplitude of the second electronic signals 32b provided to a section of the second optoelectronic device 100b (or a thermoelectric signal) according to methods and modified electric currents described above with respect to FIG. 8A-8C.

With reference to FIG. 1A-1B, in some implementations, the electrical circuitry 30 may be programed or configured to control the first electronic signals 32a provided to a section of the first optoelectronic device 100a to compensate for residual temperature variations that are not compensated by the heat compensating device (e.g., the second optoelectronic device 100b). For example, in addition to controlling the second electronic signals 32b, the electrical circuitry 30 may control a bias current provided to a section of the first optoelectronic device 100a to further stabilize a temperature of the section and thereby the optical output power, polarization, or the wavelength (e.g., the center wavelength) of the first optoelectronic device 100a. In some cases, the electrical circuitry 30 may control a current (e.g., a bias current) provided to a section of the first optoelectronic device 100a to fine tune a wavelength of light generated by the first optoelectronic device 100a.

In some examples, during a factory calibration process the electrical circuitry 30 may be programed or configured to provide second electronic signals 32b having tailored amplitude and temporal profiles, to the second optoelectronic device 100b (or a thermoelectric signal), and a user may further configure or program the electrical circuitry 30, to adjust first electronic signals 32a provided to first optoelectronic device 100a to compensate for a residual temperature variation of the first optoelectronic device 100b (that is not compensated by the heat compensating device). In some such examples, the adjustment of the first electronic signals 32a may comprise adjusting one or more bias current provided to the one or more sections of the first optoelectronic device 100a.

In various implementations, the electrical circuitry 30 may comprise a digital circuit, an analog circuit, or combination thereof. As such a factory calibration process or user post-calibration adjustment may comprise, adjusting one or more tunable electronic components in a digital or analog circuits, modifying machine executable commands executed by a processor of the electrical circuitry 30, or adjusting a parameter of an algorithm executed by a processor of the electrical circuitry 30.

In some examples, the electrical circuitry 30 may use an empirical model for controlling the first and second electronic signals 32a and 32b (e.g., the electric currents 703 and 705). In some such examples, the empirical model may be implemented as an algorithm and a set of parameters stored in a memory of the electrical circuitry 30 and executed by a processor of the electrical circuitry 30. In some cases, the value of at least a subset of parameters may be adjusted during a factory calibration process or determined based on calculated or experimental data.

In various implementations, pre/post-emphasis of a signal provided to the heat compensating device with overshoot or undershoot can be used to increase the speed at which a thermal equilibrium between the heat compensating device and the light generating optoelectronic device.

In some examples, the heat compensating device may comprise one or more heating elements (e.g., resistive pads, heat generating pads).

In various implementations, pre/post-emphasis can include timing, magnitude, and shape (e.g., specific temporal profile) of the signal provided to the heat compensating device.

In some cases, temporal profile, amplitude, timing, or other characteristics of a pre/post-emphasized signal (e.g., electrical current) may be determined based at least in part on a dimension, design, material property, electric impedance, and/or thermal impedance, of the heat compensating and the light generating device. In some cases, temporal profile, amplitude, timing, or other characteristics of a pre/post-emphasized signal (e.g., electrical current) may be determined based at least in part on a relative position of the heat compensating and the light generating device. Further temporal profile, amplitude, timing, or other characteristics of a pre/post-emphasized signal (e.g., electrical current) may be determined based on a thickness of a substrate (e.g., a chip) on which the heat compensating device and the light generating device are fabricated and/or an orientation of the heat compensating and the light generating device with respect to the substrate (e.g., p-side up or p-side down mounted).

In some cases, temporal profile, amplitude, timing, or other characteristics of a pre/post-emphasized signal (e.g., electrical current) provided to the heat compensating device, and/or a delay between the pre/post-emphasized signal and a signal provided to the light generating device may be determined based at least in part thermal mass of contact pad (e.g., amount metal deposited on a section of the heat compensating or light generating device), and/or a response time of the circuit that controls the pre/post-emphasized signal (e.g., a loop time constant such as TEC loop constant)

In some implementation, in addition to heat compensation by an adjacent device, a signal provided to the light generating device (e.g., a bias current) may adjusted, modulated, or controlled to compensate for variation of a property of light output by the light generating device (e.g., wavelength or modulation amplitude).

### Feedback Control of the Heat Compensating Device

In some implementations, the signal provided to a heat compensating device may be controlled based at least in part on a measured wavelength, or a measured wavelength change, of light generated by an optoelectronic device that is thermally controlled by the heat compensating device. In these implementations, the wavelength of light generated by the optoelectronic device may be monitored in real time (e.g., continuously, or periodically) to provide a feedback signal to an electrical circuitry that controls the heat compensating device (and possibly the light generating optoelectronic device) based at least in part on the feedback signal. The feedback signal may indicate the wavelength, or a magnitude of a wavelength change of light generated by an optoelectronic device. The heat compensating device can be fabricated on a substrate on which the optoelectronic device is fabricated and may be in thermal communication with the optoelectronic device via the substrate. In some cases, the heat compensating device can be a second optoelectronic device having the same or different design compared to the optoelectronic device. In some cases, the second optoelectronic device can be substantially identical to the optoelectronic device. In some cases, the second optoelectronic device may not generate light at least in a portion of a period during which it controls the temperature of the optoelectronic device (e.g., the first optoelectronic device) via heat exchange. In some examples, the electrical circuitry may adjust a signal (e.g., a current or voltage) provided to the heat compensating device based at least in part on the feedback signal. Additionally or alternatively, in some examples, the electrical circuitry may adjust a signal (e.g., a current or voltage) provided to the optoelectronic device based at least in part on the feedback signal. In some implementations, the electrical circuitry may adjust the signal provided to the heat compensating device to stabilize temperatures of one or more sections of the optoelectronic device and adjust the signal provided to the optoelectronic device (e.g., a phase section of the optoelectronic device) for fine tuning the wavelength of light by the optoelectronic device.

The wavelength of light can be monitored by a wavelength monitoring device configured to receive light from the optoelectronic device and generate a feedback signal indicative of a wavelength or wavelength change of the detected light. In some cases, apparatus 10 and the wavelength monitoring device can be inside a common housing. In some cases, the wavelength monitoring device can be integrated with the optoelectronic and heat compensating devices. In some implementations, the wavelength monitoring device may be fabricated on the substrate on which the heat compensating device and the optoelectronic device are fabricated.

The optoelectronic device, the wavelength monitoring device, the electrical circuitry, and the heat compensating device can form a feedback loop comprising an optical, electrical, and thermal paths or any combination of these, for closed loop control of the heat compensating device and thereby the temperature of the optoelectronic device.

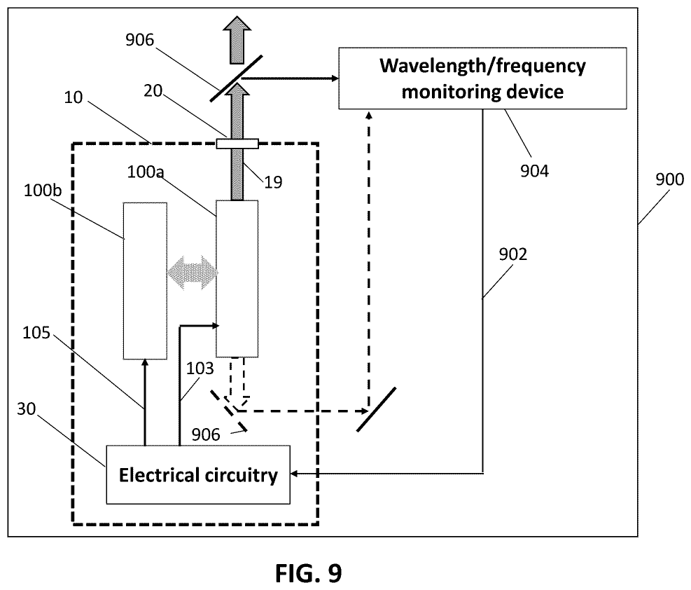

FIG. 9 schematically illustrates an example system 900 comprising an apparatus 10 that outputs light (or a light beam) 19 and a wavelength monitoring device 904 that receives a portion of the light (or a light beam) 19 output by a first optoelectronic device 100a via an output port 20 (or another auxiliary port) of the apparatus 10. In some examples, the output port 20 may comprise an output port of the optoelectronic device 100a. In some cases, the wavelength monitoring device 904 may receive a portion of light output from a front reflector or at least a portion of light output from a back reflector (or facet) of the optoelectronic device 100a.

The wavelength monitoring device 904 generates a feedback signal 902 based at least in part on the light received from the optoelectronic device 100a and provides the feedback signal 902 to the apparatus 10 (e.g., an electrical circuitry 30 of the apparatus 10). In some cases, the feedback signal 902 is indicative of a wavelength or wavelength change of the light output from apparatus 10.

In some implementations, the apparatus 10 comprises the first optoelectronic device 100a that generates light and a second optoelectronic device 100b (the heat compensating device) that is thermal communication with the first optoelectronic device 100a and controls the temperature of at least one section of the first optoelectronic device 100a. In some cases, the second optoelectronic device 100b may not generate light during the operation of apparatus 10. In some other cases, the second optoelectronic device 100b may generate light; however, light generated by the optoelectronic device 100b may not output from the apparatus 10. As described above, in some implementations, the electrical circuitry 30 may provide first electrical signals 32a (e.g., the current 703) to the first optoelectronic device 100a and second electrical signals 32b (e.g., the current 705) to the second optoelectronic device. In some cases, the cases, the first electrical current 703 is provided to a section of the first optoelectronic device 100a to control the generation of light (e.g., optical signals 20a) by the first optoelectronic device 100a. In various implementations, the first electrical current 703 may be configured to control the phase, amplitude, and/or wavelength of light generated by the first optoelectronic device 100a. For example, the first electrical current 703 can be provided to a gain section (e.g., gain section 103a) of the optoelectronic device 100a to adjust or modulate the amplitude of light and thereby optical power output by the first optoelectronic device 100a. As another example, the first electrical current 703 can be provided to a mirror (e.g., the back gain section (e.g., gain section 103a) of the optoelectronic device 100a to modulate an amplitude of light and thereby optical power output by the first optoelectronic device 100a (e.g., the back mirror 101a or front mirror 104a) to adjust, scan, or sweep the wavelength of light output by the first optoelectronic device 100a. The electrical circuitry 30 may further provide the first electrical current 703 at least a section of the second optoelectronic device 100b to control a temperature of a corresponding section of the first optoelectronic device 100a.

In various implementations, the first and the second optoelectronic devices 100a, 100b, may be fabricated on a common substrate and may have similar or different designs. In some cases, the second optoelectronic device 100b may be replaced by a thermoelectric device that is not capable of generating an output light beam. In some such cases, the thermoelectric device can be a resistive element or a TEC. In some examples, the resistive element may comprise a resistive metal trace, a resistive film (e.g., a thin or thick film), pad, or microstripline, lithographically patterned on or near the first optoelectronic device. The resistive film may comprise an alloy such as NiCr or other metallic alloys.

In some cases, the system 900 may include an optical power divider 906 (e.g., an optical beam splitter) positioned to receive light from the optoelectronic device 100a, e.g., via the output port 20 and redirect a portion of the received light to the wavelength monitoring device 904. In some cases, the optical power divider 906 may comprise a free-space optical beam splitter. In some examples, the system 900 may include one or more reflectors configured to redirect light received from the power divider 906, or from a back reflector (or a back port) or front reflector (or front port) of the optoelectronic device 100a, to the wavelength monitoring device 904.

In some cases, the power divider 906 may comprise a waveguide based optical power divider (e.g., an on-chip or fiber optic optical power divider). In some cases, the power divider 906 may comprise an on-chip directional coupler. In some cases, a waveguide (e.g., a fiber optic or on-chip) may transmit light output by the power divider 906, or via a back reflector (or a back port) or front reflector (or front port) of the optoelectronic device 100a, to the wavelength monitoring device 904.

In some cases, the wavelength monitoring device 904 may comprise an optical spectrometer. In some implementations, the wavelength monitoring device 904 may comprise an on-chip device configured to receive light at least through one input port and generate one or more signals usable for determining a wavelength or a wavelength change of the received light. In some examples, the wavelength monitoring device 904 may comprise one or more optical output ports and one or more photodetector that receive light output by respective output ports and generate one or more detection signals indicative of a power of the light received from the respective output ports. The one or more detection signals may be used, individually or in combination, to determine a wavelength or wavelength change of the light received by the wavelength monitoring device 904 from the first optoelectronic device 100a. In some cases, the wavelength monitoring device 904 may comprise at least one wavelength selective optical component between the one or more input ports and the one or more output ports. In some implementations, the wavelength selective device may comprise a Mach-Zehnder interferometer (e.g., an asymmetric Mach-Zehnder interferometer) or an Etalon interferometer. In some cases, other wavelength selective devices may be used to generate optical outputs having wavelength selective optical powers. In some cases, the feedback signal 902 may comprise the one or more detection signals generated by the wavelength monitoring device 904 and the electrical circuitry 30 may process the detection signals to determine a wavelength or wavelength change of the light received by the wavelength monitoring device 904. In some cases, the wavelength monitoring device 904 includes an internal electrical circuitry that receives the one or more detection signals and generates the feedback signal 902 indicative of a wavelength, or a wavelength change of the light received by the wavelength monitoring device 904. In some cases, the electrical circuitry 30 or the internal electrical circuitry of the wavelength monitoring device 904 may comprise a non-transitory memory storing machine readable instructions and a processor that executes the stored machine-readable instructions to determine a wavelength or wavelength change of the light received by the wavelength monitoring device 904, e.g., using the one or more detection signals. In some cases, the electrical circuitry 30 or the internal electrical circuitry of the wavelength monitoring device 904 may comprise a digital circuit and analog circuit, or a combination thereof.

In some implementations, the system 900 is configured to generate a modulated (e.g., an amplitude modulated) optical signal having a substantially time-independent wavelength (e.g., a center wavelength) or a wavelength (e.g., a center wavelength) within a specified wavelength uncertainty. In these implementations, the electrical circuitry 30 may be configured to control the second optoelectronic device 100b such that the wavelength of the optical signal remains substantially time-independent or within the specified wavelength uncertainty limit.

In some implementations, the system 900 is configured to generate an output light beam having a substantially constant optical power and a wavelength (e.g., a center wavelength) that changes over time based on a specified rate or temporal wavelength pattern/profile (e.g., lineal, or monotonous profile). For example, the wavelength can be swept between a lower and an upper bound, one or more times (e.g., periodically). In these implementations, the electrical circuitry 30 may be configured to control the second optoelectronic device 100b such the heat exchange between the first and the second optoelectronic 100a, 100b, keeps the wavelength of the first optoelectronic device 100a within a wavelength uncertainty limit centered at the specified temporal wavelength pattern/profile. For example, when the specified temporal wavelength profile comprises a linear slope (similar to variation of the wavelength 404), the electrical circuitry 30 may control the second optoelectronic device 100b such that a deviation of wavelength of the first optoelectronic device 100a from the linear slope is less than 1%, less than 5%, less than 10%, less than 20%, less than 30%, less than 50%, or any range formed by any of these values, of the wavelength uncertainty limit. In some examples, the specified wavelength uncertainty limit may comprise a spectral range smaller than 10⁻⁷, 10⁻⁶, 10⁻⁴, 1%, 3%, 5%, or 10%, or any range formed by any of these values, of a wavelength (e.g., a center wavelength) of light generated by the optoelectronic device.

In some implementations, system 900 is configured to change the wavelength of the output light beam 19 from an initial wavelength to a desired wavelength (e.g., a center wavelength) selected by a user. For example, the user may provide the desired wavelength to the electrical circuitry 30 and the electrical circuitry may adjust one or more wavelength tuning parameters of the first optoelectronic device 100a (e.g., a current provided to a mirror or a phase section of the first optoelectronic device), to tune the wavelength of the output light beam 19 to the desired wavelength. In some cases, the electrical circuitry 30 may adjust the one or more wavelength tuning parameters based on a previously measured wavelength map (e.g., a reference wavelength map). In some cases, a wavelength map may comprise wavelengths (e.g., measured wavelengths) of the output light for different values of one or more wavelength tuning parameters (e.g., currents provided to front and back mirrors 104a, 101a of the first optoelectronic device 100a). In some cases, the electrical circuitry 30 may be configured to control the second optoelectronic device 100b such the heat exchange between the first and the second optoelectronic 100a, 100b, causes the wavelength of the output light beam 19 to be tuned to the desired wavelength independent of the initial wavelength, a path (e.g., a current path) in a wavelength tuning parameter space through which the wavelength is tuned from the initial wavelength to the desired wavelength, a wavelength tuning speed at which the wavelength of the output light beam 19 is tuned, a tuning speed at which a wavelength tuning parameter is tuned.

As described above, with respect to FIG. 3, changing the wavelength of light generated by the first optoelectronic device 100a and maintaining its power substantially constant may involve adjustment of electrical currents (or voltages) provided to the front mirror 104a, back mirror 101a, and the phase section 102a, the gain section 703a and/or the SOA 705a in a complex manner. These electrical currents provided to various portions of the first optoelectronic device 100a can induce corresponding temperature changes in one or more sections of the optoelectronic device 100a and interfere with the wavelength adjustment process. Advantageously, the electrical circuitry 30 may be configured to control multiple sections of the second optoelectronic device 100b (e.g., simultaneously) to compensate the corresponding temperature changes in the sections of the optoelectronic device 100a. As such, the electrical circuitry 30 may control multiple currents provided to multiple sections of the second optoelectronic device based at least in part on the feedback signal received from the wavelength monitoring device 904.

In some implementations, the electrical circuitry 30 may be configured (e.g., programed) to adjust one or more signals (e.g., currents or voltages) provided to one or more sections of the second optoelectronic device 100b, e.g., in real time, based at least in part on a wavelength or wavelength change extracted from the feedback signal 902, or received from the wavelength monitoring device 904, to control temperature of the corresponding sections of the optoelectronic device 100a via heat exchange.

In some implementations, the electrical circuitry 30 may configured (e.g., programed) to adjust one or more signals (e.g., currents or voltages) provided to one or more sections of the first optoelectronic device 100a, e.g., in real time, based at least in part on a wavelength or wavelength change extracted from the feedback signal 902, or received from the wavelength monitoring device 904, to control (e.g., fine tune or coarse tune) the wavelength of light generated by the first optoelectronic device 100a.

In some examples, the electrical circuitry 30 may configured (e.g., programed) to adjust one or more signals (e.g., currents or voltages) provided to one or more sections of the first optoelectronic device 100a (e.g., the front and back mirrors) to tune (e.g., coarse tune) the wavelength of light generated by the optoelectronic device 100a to a target wavelength and use the feedback signal 902, a wavelength or wavelength change extracted from the feedback signal 902 or received from the wavelength monitoring device 904, to stabilize a temperature of at least one section of the optoelectronic device 100a by controlling a current provided to the second optoelectronic device 100b. Additionally, the electrical circuitry 30 may use the feedback signal 902, a wavelength or wavelength change extracted from the feedback signal 902 or received from the wavelength monitoring device 904 to fine tune the wavelength of light generated by the first optoelectronic device 100a, e.g., to reduce or potentially eliminate wavelength inaccuracies caused by temperature variations not fully compensated by the second optoelectronic device 100b. In some cases, the electrical circuitry 30 may use control a current provided to a phase section of the first optoelectronic device 100a based on the feedback signal 902 to fine tune the wavelength of light generated by the first optoelectronic device 100a.

In some examples, the values of one more circuit parameters of the electrical circuitry 30 (or used in an algorithm executed by the electrical circuitry 30), may be determined using a calibration process (e.g., factory calibration process). In some cases, the calibration process may comprise one or more of: adjusting the circuit parameters while modulating the amplitude and monitoring the wavelength of light generated by the first optoelectronic device 100a in an open loop configuration, adjusting the circuit parameters while changing and monitoring the wavelength of light generated by the first optoelectronic device 100a in an open loop configuration, characterizing the current-voltage characteristics of the first and/or the second optoelectronic devices 100a, 100b, individually or together (e.g., while exchanging heat). In some cases, other calibration processes may be used.

In some examples, modulating the wavelength may comprise adjusting signals (current or voltages) provided to one or more sections of the first optoelectronic device 100a, and adjusting the circuit parameters may comprise adjusting the parameters that control signals provided to one or more respective sections of the second optoelectronic device 100b.

In some cases, e.g., during calibration process, a hysteresis behavior of the wavelength or optical power of light generated by the first optoelectronic device 100a with respect to one or more signals provided to one or more sections of the first optoelectronic device 100a, may be characterized. In some such cases, e.g., when such hysteresis behavior is caused by or is linked to temperature variation of the corresponding sections, the circuit parameters of the electrical circuitry 30 may be adjusted to reduce such hysteresis behavior during the closed loop operation of the system 900 and the wavelength and/or optical power of light generated by the first optoelectronic device 100a is modulated, scanned, or otherwise adjusted.

In some examples, where the electrical circuitry 30 is configured to switch or change the wavelength of the light beam 19 output by the first optoelectronic device 100a according to a predefined sequence of wavelengths or continuously tune the wavelength of the light output by the first optoelectronic device 100a from an initial wavelength to a final wavelength, during the calibration process a wavelength map (e.g., a reference wavelength map) and/or a wavelength difference map (also referred to as wavelength hysteresis map) may be used to calibrate the electrical circuitry 30. As described above, in some cases, the wavelength map may comprise measured wavelengths of the output light for different values of one or more wavelength tuning parameters (e.g., currents provided to front and back mirrors 104a, 101a of the first optoelectronic device 100a). In some cases, the wavelength map can be generated by slowly changing the wavelength tuning parameters such that the measured wavelength at each point of the map remains substantially constant over time for the corresponding values of the wavelength tuning parameters. In some such examples, the calibration process may comprise adjusting the one or more parameters of the electrical circuitry 30 (e.g., parameters that control the currents 32a provided to the second optoelectronic device 100b), while controlling the currents or voltages provided to wavelength tuning sections (e.g., the front mirror 104a, back mirror 101a, and the phase section 102a) according to a predefined current path in the wavelength map or the wavelength difference map. A current path may comprise a sequence of values for two wavelength tuning parameters (e.g., the electrical current provided to the front mirror 104a, the back mirror 101a, or phase section 102a) used to tune the wavelength of the output light from an initial wavelength to a final wavelength. In some examples, the current paths may be selected based at least in part on a predefined sequence of wavelengths or a predefined wavelength range. The predefined sequence of wavelengths or the predefined wavelength range may be associated with a specific application or may be provided by a user or customer.

In some cases, a wavelength map may comprise a two-dimensional wavelength map generated by scanning the currents provided to two wavelength tuning sections of the first optoelectronic device 100a (e.g., the front mirror 104a and the back mirror 101a) within two predefined ranges. In some such cases, the electric currents provided to the two wavelength tuning sections may be scanned or changed with a slow speed to reduce or potentially eliminate any wavelength uncertainty associated with thermal effects and thereby making the wavelength map independent of the scanning direction of the currents provided to two wavelength tuning sections (e.g., from low to high current and vice versa). Such wavelength map may be referred to as a reference wavelength map. A reference wavelength map provides a reference wavelength for each pair of values for the currents provided to two wavelength tuning sections of the first optoelectronic device 100a. In some examples, changing an electric current provided to a wavelength tuning section of the first optoelectronic device 100a by a slow speed may comprise changing the electric current at a rate smaller than 500 milliampere per second (mA/s), smaller than 250 mA/s, smaller than 100 mA/s, smaller than 50 mA/s, smaller than 10 mA/s, or any range formed by any of these values or possibly larger or smaller values.

In some cases, a wavelength difference map may comprise a two dimensional wavelength map generated by generating a first wavelength map by performing a first wavelength scan (e.g., a first raster scan), generating a second wavelength map by performing a second wavelength scan (e.g., a second raster scan), and subtracting the wavelengths in the second wavelength map from respective wavelengths in the second wavelength map, where the respective wavelengths are wavelengths generated by the same values of the currents provided to two wavelength tuning sections in the first and the second wavelength maps. In some cases, the first wavelength scan (also referred to as a first sweep condition) comprises scanning the currents provided to the two wavelength tuning sections of the first optoelectronic device 100a (e.g., two mirrors or a mirror and a phase section) within two predefined ranges in a first direction, via first electrical current path, or by a first tuning speed, and the second wavelength scanning the electric currents provided to two wavelength tuning sections of the first optoelectronic device 100a within the two predefined ranges in a second direction, via second current path, or by a second tuning speed, different from (e.g., opposite to) the first direction first path, or first tuning speed.

In some such cases, during the first and second wavelength scans the electric currents provided to the two wavelength tuning sections may be scanned with a tuning speed that is large enough to cause the respective wavelengths in the first and the second wavelength maps to be different. In some examples, the tuning speed can be larger than 250 milliampere per microsecond, greater than 250 milliampere per microsecond, greater than 500 milliampere per microsecond, greater than 1 milliampere per nanosecond, greater than 10 milliampere per nanosecond, greater than 100 milliampere per nanosecond or larger values. In some cases, the first wavelength scan may comprise scanning the currents provided to two wavelength tuning sections with a first tuning speed via a first electrical current path and the second wavelength scan may comprise scanning the currents provided to two wavelength tuning sections with a second tuning speed different than the first tuning speed. In some cases, the second tuning speed can be larger than the first tuning speed. In some cases, the first tuning speed may be selected to reduce or potential eliminate the impact of thermal effects on the wavelength of light generated by the first optoelectronic device and the second tuning speed can be selected to be within a tuning speed range used during operation of the first optoelectronic device. In some such cases, the first wavelength generated by the first scan can be a reference wavelength map. In some examples, the first tuning speed (or rate) can be smaller than 500 milliampere per second (mA/s), smaller than 250 mA/s, smaller than 100 mA/s, smaller than 50 mA/s, smaller than 10 mA/s, or smaller values. In some examples, the second tuning speed can be greater than 250 milliampere per microsecond, greater than 250 milliampere per microsecond, greater than 500 milliampere per microsecond, greater than 1 milliampere per nanosecond, greater than 10 milliampere per nanosecond, greater than 100 milliampere per nanosecond or larger values.

In some implementations, the wavelength difference map may indicate regions of the wavelength map within which the difference between the respective wavelengths (also referred to as wavelength error) is larger than a threshold value. In some examples, the threshold value can be from 1 pm to 5 pm, from 5 pm to 10 pm, from 10 pm to 50 pm, from 50 pm to 100 pm, from 100 pm to 500 pm, from 500 pm to 1 nm, from 1 nm to 10 nm, from 10 nm to 100 nm, or any ranges formed by these values or larger or sampler values.

### Integrated Wavelength Monitoring Device

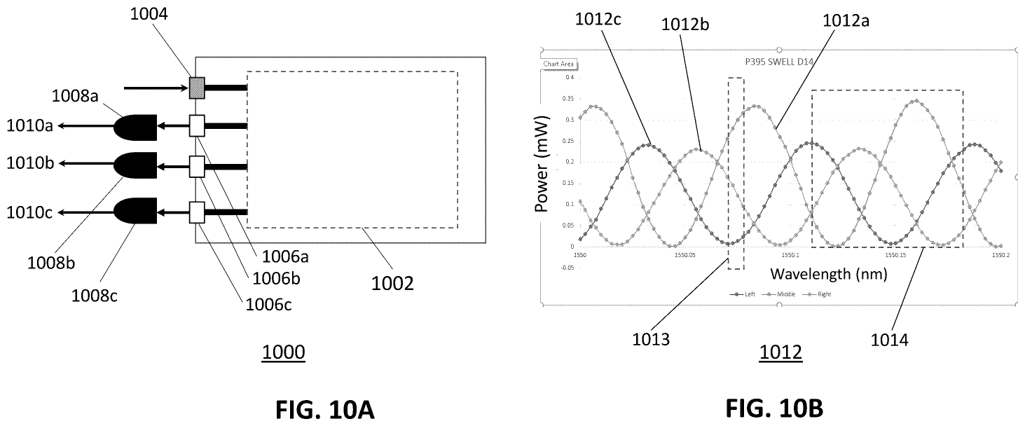

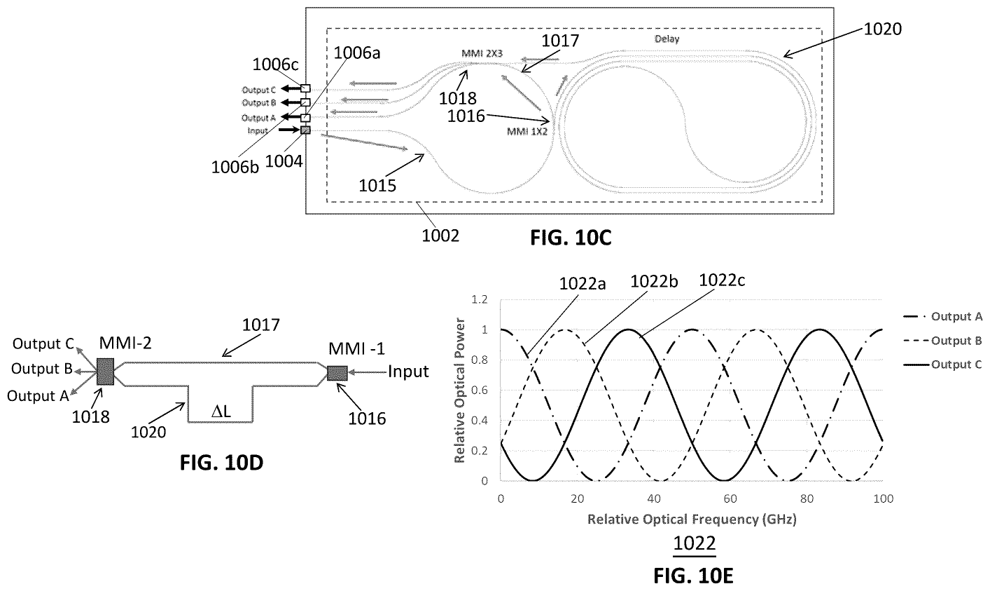

FIG. 10A schematically illustrates an example optical device 1000 that may be used in the wavelength monitoring device 904 of the system 900 to measure and monitor wavelength or wavelength changes of light received from the optoelectronic device 100a. In the example shown, the optical device 1000 may comprise a wavelength selective optical component 1002 (e.g., an interferometer), one input port 1004 through which the wavelength selective optical component 1002 (herein referred to as the optical component 1002) receives light from the optoelectronic device 100a (e.g., via the output port 20 of the apparatus 10), three photodetectors 1008a-1008c that receive light transmitted through the optical component 1002, and three output ports 1006a-1006c through which the photodetectors 1008a-1008c receive the light transmitted through the optical component 1002 via three different optical paths. In some cases, the optical component 1002 may comprise the output ports 1006a-1006c. The photodetectors 1008a-1008c are configured to generate three detection signals 1010a-1010c (e.g., three photocurrent) proportional to or indicative of the optical power of light received from the respective output of the output ports 1006a-1006c. The optical component 1002 may be configured to generate three transmitted light beams having wavelength selective optical powers. In some cases, the optical component 1002 comprises a Planar Light Circuit (PLC) (e.g., an on-chip or monolithic optical component) formed by a network of interconnected and/or coupled optical waveguides fabricated on a substrate (e.g., a chip). In addition of alternatively, the optical component 1002 may comprise one or more fiber optic waveguides. In some examples, the optical component 1002 may be fabricated, mounted, or integrated on the substrate on which the optoelectronic device 100a is fabricated or mounted. In some cases, the optical input port 1004 and the output ports 1006a-1006c may be optically connected to the output port 20 (or an output of the optoelectronic device 100a), and the photodetectors 1008a-1008c, respectively (e.g., using Photonic Wire Bonds). In some cases, the optical component 1002 there may generate one or two outputs monitored by one or two photodiodes. In various implementations, a number of outputs generated by the optical component 1002 may depend on a wavelength resolution required for monitoring the wavelength.

In some examples, the wavelength selective optical component 1002 may comprise at least one asymmetric Mach-Zehnder interferometer. An optical power (or an intensity) of an individual transmitted light beam can change deterministically as function of the wavelength of the input light beam. In some examples, the three different transmitted light beams change as three different functions of the wavelength of the input light beam. In some such examples, these three different functions may be used to uniquely determine a wavelength of the input light beam (received via input port 1004), at least in an operational wavelength range. In some cases, each individual function of the three different functions may comprise a periodic function having a period (also referred to as the free spectral range of the corresponding optical path). In some such cases, the operational wavelength range can be smaller than 100%, smaller than 50%, smaller than 25%, smaller than 10%, or smaller than 5% of a period (e.g., the smallest period) of the three different periodic functions.

FIG. 10B shows a graph 1012 comprising calculated optical powers 1012a-1012c of three transmitted light beams generated by an example optical device 1000 as a function of the wavelength or center wavelength (λᵢₙ) of the input light beam. In some cases, where the detection signals 1010a-1010c are proportional to the optical power of the light beams received by the respective detectors, the variation of the detection signals 1010a-1010c with respective to λᵢₙ, can be substantially identical to variation of optical powers 1012a-1012c with respective to λᵢₙ. As such, the calculated optical powers 1012a, 1012b, and 1012c essentially represent the detection signals 1010a, 1010b, and 1010c, respectively.

In the example shown, optical power of an individual transmitted light beam varies periodically as a function of λᵢₙ. As such, λᵢₙ or a change of λᵢₙ (Δλᵢₙ) cannot be determined based on the optical power of a single transmitted optical beam. In some cases, the optical power of two or more transmitted optical beams may be used to determine the λᵢₙ and/or Δλᵢₙ within an operational wavelength range. In some cases, an operational range (e.g., operational wavelength range 1013 and 1014) can be smaller than a period (e.g., the smallest period) of detection signals 1010a, 1010b, and 1010c. In some cases, an operational wavelength range (e.g., operational wavelength range 1013) can be smaller than 25% of a period (e.g., the smallest period) of detection signals 1010a, 1010b, and 1010c. In various implementations, the period (or the free spectral range) of the detection signals 1010a, 1010b, and 1010c can be from 5 GHz to 10 GHz, from 10 GHz to 40 GHz, from 40 GHz to 50 GHZ, from 50 GHz to 60 GHz, from 60 GHz to 70 GHz, from 70 GHz to 100 GHz, from 100 GHZ to 150 GHz, from 150 GHz to 200 GHz or any ranges formed by these values or smaller or larger values.

In some cases, the wavelength selective optical component 2002 may comprise an optical interferometer or an optical filter. For example, the wavelength selective optical component 1002 may comprise one or more Etalon interferometers.

In some cases, the wavelength selective optical component 1002 may comprise an integrated photonic device or a fiber optic device.

In some implementations, the optical device 1000 may comprise less than three output ports (e.g., one or two output ports). In these implementations, the wavelength of the input light beam may be determined using one or two detection signals.

FIG. 10C schematically illustrates an integrated photonic circuit depicting an example waveguide configuration, comprising a plurality of waveguides, for the wavelength selective optical component 1002 shown in FIG. 10A. The integrated photonic circuit comprises a first waveguide section 1015 optically connecting the input port 1004 to a single input port of a first photonic multimode interferometer (MMI) 1016 having two output ports. In some embodiments, MMI 1016 may comprise a Y-shape optical coupler or power splitter. A first output port of the MMI 1016 is optically connected by a second waveguide section 1017 to one of the two input ports of a second multimode interferometer (MMI) 1018 having three output ports each optically connected to one of the three output ports 1006a-1006c of the wavelength monitoring device 1000. In some embodiments, MMI 1018 may comprise a 2 by 3 optical coupler or power splitter. In some embodiments, the optical properties of one or both MMIs 1016, 1018 may cause differences in the wavelength (frequency) dependencies of optical powers output by the individual outputs of the second MMI 1018 (outputs A, B, C). A second output port of the MMI 1016 is optically connected by a third waveguide section 1020 to the second input port of the second photonic multimode interferometer (MMI) 1018. In some embodiments, the third waveguide section 1020 may comprise a very long waveguide configured to provide an optical delay between optical signals provided to the two input ports of the second MMI 1018. In some embodiments, an optical path difference between the second 1017 and third 1020 waveguide sections may be configured to provide a periodic variation of optical power output by the individual output ports of the second multimode interferometer (MMI) 1018 and thereby the output ports of the wavelength monitoring device 1000. FIG. 10D schematically illustrates a simplified photonic circuit diagram for the integrated photonic circuit shown in FIG. 10C depicting the two MMIs 1016, 1018 and the second and third waveguide sections 1017, 1020 optically connecting the two output ports of the first MMI 1016 to the two input ports of the second MMI 1018. In some embodiments, the integrated photonic circuit shown in FIG. 10C and the corresponding integrated photonic circuit diagram shown in FIG. 10D, may comprise an asymmetric Mach-Zehnder interferometer formed between two optical couplers or optical splitters or two MMIs. In some embodiments, the optical path length difference (ΔL) between the second and third waveguide sections 1017, 1020 that optically connect the output ports of the first MMI 1016 to the input ports of the second MMI 1018 may result in variation of optical powers output by individual outputs of the second MMI 1018 (Output A, B, C) with respect to the wavelength of input light.

FIG. 10E shows a plot 1022 comprising relative optical powers 1022a-1022c output from three different output ports 1006a-1006c of the integrated photonic circuit shown in Figured 10C as a function of the relative optical frequency of light received by the input port 1004 (input light). In some examples, the relative optical frequency may be measured with respect to a center optical carrier frequency (corresponding to the center wavelength λᵢₙ) of the input light beam provided to the input port 1004. Similar to graph 1012, in graph 1022 optical powers 1022a-1022c of individual output (transmitted) light beams vary periodically as a function of relative optical frequency. In some cases, the wavelength dependence of two or more of the optical powers 1022a-1022c may be used to determine the optical frequency of the input light or a change of the optical frequency of input light within the operational frequency range of the laser system (associated with the operational wavelength ranges described above with respect to FIG. 10B).

In some implementations, during a factory calibration procedure a reference wavelength map may be generated by slowly varying two electric currents (wavelength control currents) provided to two wavelength tuning sections (e.g., the front and the back mirrors) and measuring the wavelength at each pair of values the two electric currents using a wave meter or an optical spectrometer. In some implementations, the two electric currents may be varied slow enough to significantly reduce or potentially eliminate thermal effects that may cause wavelength errors, e.g., when a point in the reference wavelength map is reached via different paths. In some cases, the two electric currents may be varied at a rate smaller than 500 milliampere per second (mA/s), smaller than 250 mA/s, smaller than 100 mA/s, smaller than 50 mA/s, smaller than 10 mA/s, or any range formed by any of these values or possible larger or smaller. For example, if a point in the reference wavelength map represented by a pair of wavelength control currents I_{w10} and I_{w20} is reached from a larger value of I_{w1} by reducing I_{w1} and keeping I_{w2} fixed at I_{w20}, and then is reached from a larger value of I_{w2} by reducing I_{w2} and keeping I_{w1} fixed at I_{w10}, the measured wavelengths at I_{w10} and I_{w20} would be substantially equal (e.g., within ±1 pm, ±5 pm, ±10 pm, or ±100 pm, or any range formed by any of these values or possibly larger or smaller values).

The reference wavelength map may be stored in a memory of electrical circuitry 30. During an operational period, for given values of wavelength control currents I_{w1} and I_{w2} (e.g., selected by a user or an algorithm), the electrical circuitry 30 may use the feedback signal 902 to determine the wavelength of light output by the first optoelectronic device 100a, compare the determined wavelength with the corresponding wavelength from the reference wavelength map (the wavelength at I_{w1} and I_{w2}) to determine a wavelength error, and adjust at least the electric current 705 based at least in part on the wavelength error. In some cases, the electrical circuitry 30 may adjust at least the electric current 703 based on the wavelength error.

### Characterizing Hysteresis Behaviors

In some cases, a temperature change in one or more sections of an optoelectronic device caused by changing the one or more signals (e.g., currents or voltages) provided to the one or more sections, may result in a hysteresis behavior when adjusting or modulating a characteristic of light generated by the optoelectronic device. In some cases, such hysteresis behavior can be reduced, mitigated, or potentially eliminated, with thermal compensation by a heat compensating device (e.g., an adjacent optoelectronic device) that is in thermal communication with the optoelectronic device.

In some cases, a hysteresis behavior may be characterized, e.g., during or before a calibration process, to identify signals, signal values, rate of change of signal values, that cause and control the hysteresis behavior. The outcomes of such characterization may be used to calibrate or program the electrical circuitry that controls the heat compensating device (e.g., electrical circuitry 30) to reduce or potentially eliminate the hysteresis behavior.

In some cases, the hysteresis characterization may comprise changing a characteristic (e.g., wavelength or optical power) of light output by the optoelectronic device from a first value to a second value via at least two different paths in the corresponding tuning parameter space or changing a characteristic of light output the optoelectronic device from a first value to a second value and back to the first value using a single tuning parameter. In various implementations, a hysteresis behavior may be measured and characterized at different current variation speeds and different timescales.

In some cases, the outcome of the hysteresis characterization may be used to validate the performance of a thermal compensation algorithm used by a power supply or control system (e.g., the electrical circuitry 30) for controlling the heat compensating device (e.g., the second optoelectronic device 100b).

In some cases, the outcome of the hysteresis characterization may be used to adjust one or more control parameters (also referred to as circuit parameters) of the electrical circuitry 30 (or an algorithm used by the electrical circuitry 30), to reduce an error (e.g., wavelength error, power error, or the like) measured during hysteresis characterization. In some cases, one or more control parameters of the electrical circuitry 30 (or an algorithm used by the electrical circuitry 30), may be adjusted to reduce thermal compensation provided by the heat compensating device to improve the energy efficiency of the system during an operation of the optoelectronic device without increasing the wavelength error.

In some cases, the outcome of the hysteresis characterization may be used to adjust one or more control parameters of the electrical circuitry 30 (or an algorithm used by the electrical circuitry 30), to reduce an error (e.g., wavelength error, power error, or the like) measured during hysteresis characterization by fine tuning a current provided to the light generating optoelectronic device.

As described above, in some cases, wavelength hysteresis behavior of light source may be characterized by a wavelength difference map that represents regions of a wavelength map within which a difference between wavelengths measured via different paths within the wavelength map exceeds a threshold value (a lower bound).

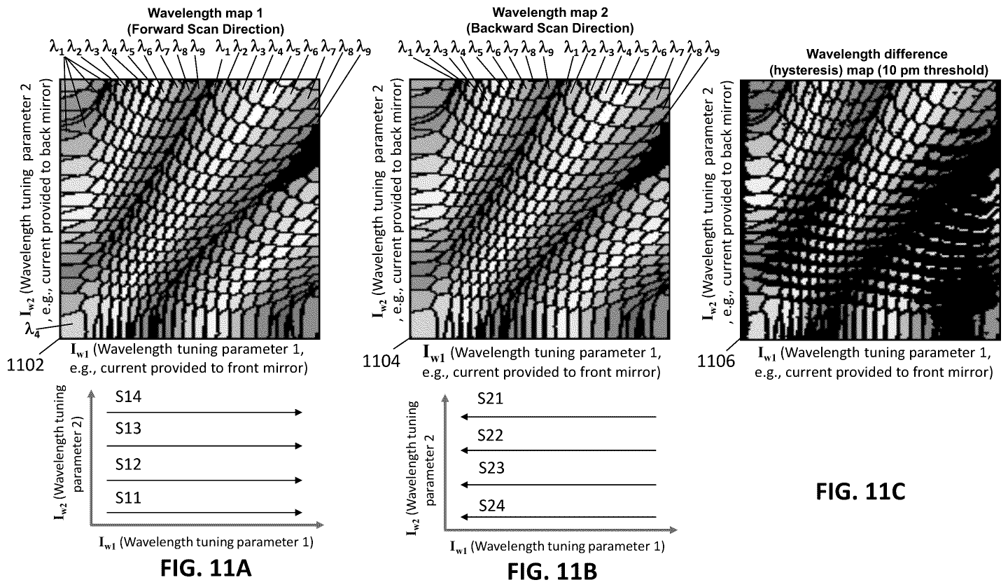

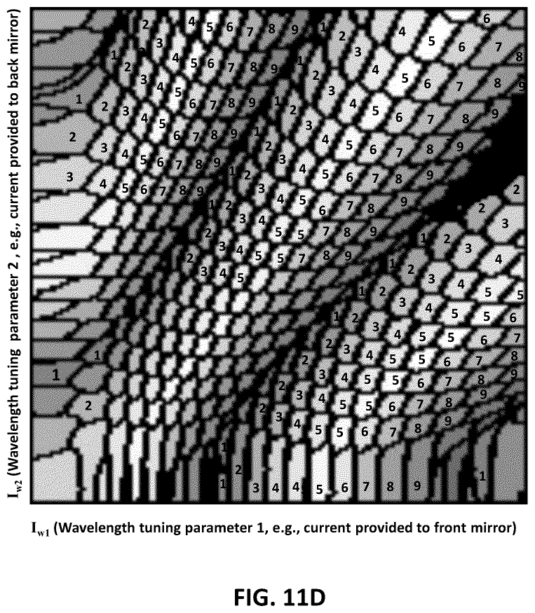

FIG. 11A illustrates an example wavelength map 1102 (top panel) obtained by raster scanning (bottom panel) the wavelength control electric currents values I_{w1} and I_{w2} provided to the front and back mirrors of the first optoelectronic device 100a, respectively, in a forward direction. In some cases, raster scanning in the forward direction comprises scanning I_{w1} from an initial value to a first end value larger than the initial value for different values of I_{w2}, while I_{w2} is increased from the initial value to a second end value. In some examples, I_{w1} and I_{w2} may be scanned by changing I_{w1} and I_{w2} continuously or in a stepwise manner. In the wavelength map 1102 the black regions represent modal boundaries (e.g., boundaries indicating a change of the oscillating optical mode in the laser cavity). In some cases, for a given value of I_{w2} increasing I_{w1} may result in a periodic variation of the wavelength of the light output by the laser (along a line parallel to I_{w1} axis). For example, when I_{w2} is near the upper limit shown in the plot as shown in FIG. 11A, increasing I_{w1} from a value closer to the lower limit show in the plot to the upper limit based on FIG. 11A (from left to right) comprises two cycles of gradual decrease of the output wavelength from λ₁ to λ₉ (where λ₁>λ₂>λ₃>λ₄>λ₅>λ₆>λ₇>λ₈>λ₉) with a sudden jump from λ₉ to λ₂. In some examples, λ₁ to λ₉ may each represent an average wavelength within a modal zone (a zone depicted by the thick black lines/boundaries). In some examples, λ₁ to λ₉ may represent a difference between an average wavelength within a modal zone and a reference wavelength (e.g., the wavelength of light output by laser when I_{w2} and/or I_{w1} are set to a lowest or highest limits or other reference values). Similarly, for a given value of I_{w1}, increasing I_{w2} may result in a periodic variation of the wavelength of the light output by the laser. For example, when I_{w1} is near the lower limit shown in FIG. 11A, increasing I_{w2} from a value substantially at the lower limit shown to a value near the upper limit, based on FIG. 11A, comprises a gradual increase of the output wavelength from λ₄ to λ₁, an abrupt decay from λ₁ to λ₈, and a second cycle of gradual increase from λ₈ to λ₁. FIG. 11A shows a similar cyclic variation of the out wavelength with respect to I_{w2} for large values of I_{w2}. FIG. 11A shows a similar cyclic variation of the out wavelength with respect to I_{w1} for smaller values of I_{w2}. FIG. 11D illustrates the example wavelength difference map shown in FIG. 11A with numerically labeled modal zones. Numerical values represent average wavelengths within each modal zone where smaller values represent larger wavelengths. An example forward raster scan is shown in the bottom panel of FIG. 11A. The forward raster scan comprises four scans (S11, S12, S13, and S13), where I_{w1} is continuously scanned from left to right at four different I_{w2} values from bottom to top.

FIG. 11B illustrates an example wavelength map 1104 (top panel) obtained by raster scanning (bottom panel) the wavelength control electric currents values I_{w1} and I_{w2} provided to the front and back mirrors of the first optoelectronic device 100a, respectively, in a backward direction. Variation of wavelength of the light output by the laser through different modal zones (zones indicated by thick back lines/boundaries) in wavelength map 1104 is similar to wavelength map 1102. Accordingly, λ₁ to λ₉ can represent average wavelengths within respective modal zones or a difference between an average wavelength within a modal zone and a reference wavelength (e.g., the wavelength of light output by laser when I_{w2} and/or I_{w1} are set to a lower or higher level or possibly the lowest or highest limits or other reference values).

In some cases, raster scanning in the backward direction comprises scanning I_{w1} from an initial value to a first end value smaller than the initial value for different values of I_{w2}, while I_{w2} is decreased from the initial value to a second end value. An example backward raster scan is shown in the bottom panel of FIG. 11B. The backward raster scan comprises four scans (S21, S22, S23, and S23), where I_{w1} is continuously scanned from right to left at four different I_{w2} values from to bottom.

The black regions in the wavelength maps 1102 and 1104 represent mode boundaries separating wavelength regions within which the first optoelectronic device operates based on different optical modes. In some cases, a mode boundary corresponds to values of I_{w1} and I_{w2} associated with modal transition and/or resulting in an unstable modal behavior of the optoelectronic device (e.g., mode hoping). Different shades (within the boundaries defined by thick black lines) on the wavelength maps 1102 and 1104 depict different wavelengths of the light output by the optoelectronic device.

In some cases, both I_{w1} and I_{w2} may be scanned in a step wise manner by sequentially adjusting I_{w1} to N discrete values and I_{w2} to M discrete values, to generate a wavelength map with N×M wavelengths corresponding to N×M values of I_{w1} and I_{w2}. In some examples, N=M=250. In some examples, M and N can be from 5 to 10, from 10 to 20, from 20 to 50, from 50 to 100, from 100 to 150, from 200 to 250, from 250 to 300, from 300 to 500, from 500 to 1000, from 1000 to 10000 or other ranges formed by these values or larger or smaller values.

FIG. 11C illustrates an example wavelength difference map 1106 (also referred to as a wavelength hysteresis map) obtained by subtracting the wavelength map in FIG. 11B from the wavelength map in FIG. 11A and identifying values of I_{w1} and I_{w2} at which a difference between respective wavelengths on the first and the second wavelength maps 1102 and 1104 (measured at I_{w1} and I_{w2}), is larger than a threshold value (a lower bound value). The black regions in the wavelength difference map 1106 depict either mode boundaries or regions where a difference between respective wavelengths in the wavelength maps shown in FIG. 11A and FIG. 11B is larger than 10 pm (a selected threshold value).

In some examples, a wavelength difference map may be generated by subtracting the respective wavelengths of two wavelength maps that are not generated by forward and backward raster scanning as described above. For example, a wavelength difference map may represent the difference between two wavelength maps generated by a changing I_{w1} and I_{w2} via a first set of current paths and a second set of current paths different from the first set oy current paths. In some cases, at least one current path in the first set can be different from the second set. In some cases, at least one current path in the first set may start from a first initial point (I_{w10}, I_{w20}) and end with a final point (I_{w1f}, I_{w2f}), and at least one current path in the second set may start from a second initial point (I′_{w10}, I′_{w20}), different from the first initial point (I_{w10}, I_{w20}), and also end with the same final point (I_{w1f}, I_{w2f}). Various paths having different shapes, initial points, and end points or any combination of these may be used in the first and set of current paths. In some cases, I_{w1} and I_{w2} can be swept or changed with different speeds along different current paths.

In some cases, during a calibration procedure (e.g., factory calibration procedure) of the apparatus 10 or the system 900, a first difference wavelength map (e.g., difference wavelength map 1106) may be generated using an initial set of control parameters (also referred to as circuit parameters) of the electrical circuitry 30 (or an algorithm executed by the electrical circuitry 30), based on a threshold wavelength error. Next, the one or more control parameters may be adjusted to reduce an area of the regions of the first difference wavelength map where the wavelength difference exceeds the threshold wavelength error (the black regions in the wavelength map 1106). Next, a second difference wavelength map may be generated using the adjusted control parameters and based on the same threshold wavelength error. If the area of the regions within which wavelength difference exceeds the threshold wavelength error is reduced below a target value, the adjusted values of the control parameters may be used as factory settings for the apparatus 10 or the system 900.

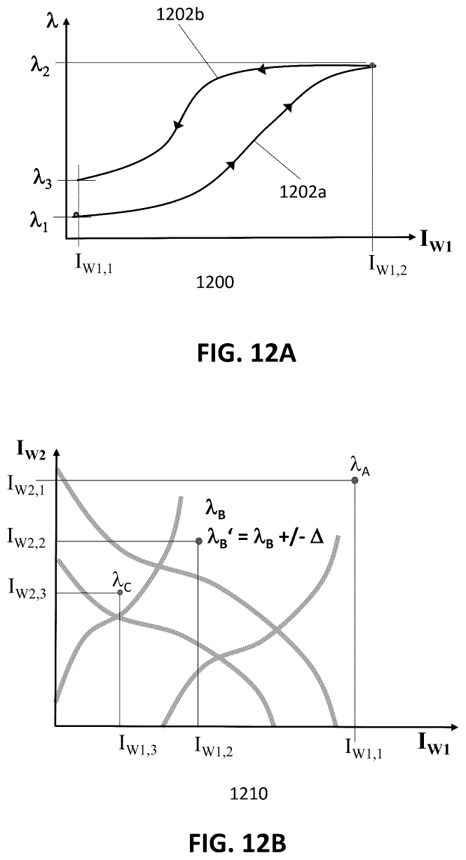

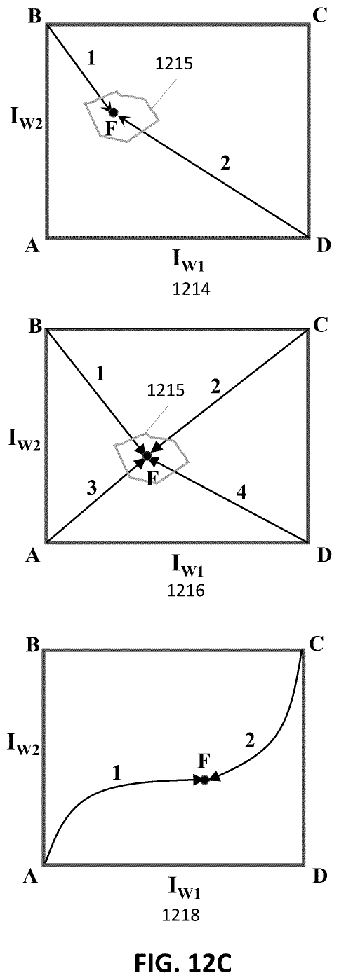

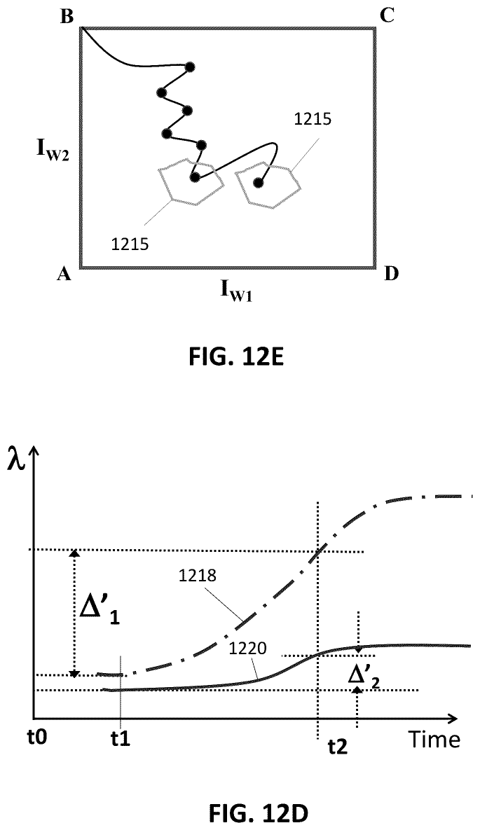

FIG. 12A illustrates an example hysteresis behavior of the wavelength (λ) of light output by an optoelectronic device (e.g., a wavelength tunable laser) with respect to a single wavelength tuning current (I_{w1}) provided to a wavelength tuning section (e.g., a reflector) of the optoelectronic device. In the example shown, starting from an initial value of I_{w1,1}, I_{w1} is increased to I_{w1,2} with a rate R1, and in response to this change the A increases from λ₁ to λ₂ via the path 1302a. Next the current I_{w1} is decreased from I_{w1,2} back to I_{w1,1}, with rate R2 and in response to this change the λ decreases from λ₁ to λ₃ via the path 1202b different from the path 1202a. In some, examples λ₁ can be substantially equal to to λ₃. In some, examples a difference between λ₁ and λ₃ may change by changing one or both of R1 and R2. In some cases, the path 1202a, path 1202b, and/or a difference between them, may change by changing one or both of R1 and R2. In some implementations, the difference between the path 1202a, path 1202b may be reduced or potentially eliminated by putting the optoelectronic device in communication with heat compensating device (e.g., another optoelectronic device), and controlling the heat generation and dissipation at least in a section of the heat compensating device to balance the heat generation and dissipation in the optoelectronic device. For example, the electrical circuitry 30 may be calibrated, or programed to adjust a magnitude and a rate of change of the second current 705 provided to the second optoelectronic device 100b such that the heat exchange between the first and the second optoelectronic devices 100a, 100b, reduces the difference between the path 1202a, path 1202b. In some cases, the electrical circuitry 30 may be configured to reduce or potentially eliminate the hysteresis effect in using an open loop control scheme (without using a feedback signal). In such cases, the electrical circuitry 30 may adjust the second current 705 based at least in part one first electrical current 703. In some cases, the electrical circuitry 30 may be configured to reduce or potentially eliminate the hysteresis effect in using a closed loop control scheme. In such cases, for example, the electrical circuitry 30 may adjust the second current 705 based at least in part on the feedback signal 902 received from the wavelength monitoring device.

FIG. 12B is an example portion of a wavelength map 1200 illustrating the wavelength (λ) of light output by the first optoelectronic device 100a (e.g., a wavelength tunable laser) as a function of two currents I_{w1}, I_{w2} provided to two wavelength tuning sections (e.g., the front and back reflectors) of the first optoelectronic device 100a when the control parameters of the electrical circuitry 30 are initially selected. In some cases, the initial selection of the control parameters may be based on an empirical model, previous measurements, a set of previously used parameter values, and the like. As described above, I_{w1} and I_{w2} define a two-dimensional parameter space for wavelength tuning. The gray lines represent modal boundaries or values of I_{w1} and I_{w2} that may cause unstable modal behavior of the optoclectronic device. In some cases, tuning I_{w1} and I_{w2} from a first initial point (I_{w1,1}, I_{w2,1}) in the wavelength map 1210 to a final point (I_{w1,2}, I_{w2,2}) tunes the wavelength of the optoelectronic device to Δ_{B}, while tuning I_{w1} and I_{w2} from a second initial point (I_{w1,3}, I_{w2,3}) in the wavelength map 1210 to the same final point (I_{w1,2}, I_{w2,2}) tunes the wavelength of the optoelectronic device to λ_{B}′=λ_{B}±Δ, where Δ is a wavelength error. In some cases, the wavelength error Δ can be associated with thermal effects in one or more sections of the first optoelectronic device 100a.

In some implementations, the control parameters of the electrical device 30 may be adjusted to reduce or potentially eliminate the wavelength error Δ by at least controlling the currents provided to one or more sections of the first optoelectronic device 100 in communication with heat compensating device (e.g., another optoelectronic device), and controlling the heat generation and dissipation at least in a section of the heat compensating device to balance the heat generation and dissipation in the optoelectronic device. For example, the electrical circuitry 30 may be calibrated, or programed to adjust a magnitude and a rate of change of the second current 705 provided to the second optoelectronic device 100b such that the heat exchange between the first and the second optoelectronic devices 100a, 100b, reduce the wavelength error Δ.

In some cases, a calibration procedure may comprise tuning I_{w1} and I_{w2} from the first initial point (I_{w1,1}, I_{w2,1}) to the final point (I_{w1,2}, I_{w2,2}) along a first path, with a first tuning speed v1, tuning I_{w1} and I_{w2} from the second initial point (I_{w1,3}, I_{w2,3}) to the same final point (I_{w1,2}, I_{w2,2}) along a second path at a second tuning speed v2, determining a first wavelength error Δ1, adjusting one or more control parameters of the electrical circuitry 30, tuning I_{w1} and I_{w2} from the same initial points to the final point along the same paths, determining a second wavelength error Δ2 and if Δ2 is smaller than an acceptable wavelength uncertainty (e.g., smaller than ±1 pm, ±5 pm, ±10 pm, or +100 pm, or larger or smaller values) using the adjusted values of the control parameters as factory preset. In some examples, if Δ2 is larger than the acceptable wavelength uncertainty, procedure may be repeated to further adjust the control parameters until Δ becomes is smaller than the acceptable wavelength uncertainty. In some cases, v1 and/or v2 can be greater than 250 milliampere per microsecond, greater than 250 milliampere per microsecond, greater than 500 milliampere per microsecond, greater than 1 milliampere per nanosecond, greater than 10 milliampere per nanosecond, greater than 100 milliampere per nanosecond or larger values. In some cases, v1 can be smaller than 500 milliampere per second (mA/s), smaller than 250 mA/s, smaller than 100 mA/s, smaller than 50 mA/s, smaller than 10 mA/s, or smaller values.

In some cases, the first and the second tuning speeds v1 and v2 can be substantially equal. In some such cases, first tuning speed v1 (or the second tuning speed v2) may be selected to be larger than a lower bound for a tuning speed at which I_{w1} and I_{w2} will be tuned during operation of the first optoelectronic device 100a. In some cases, the first tuning speed v1 can be different than the second tuning speed v2, and the larger of the v1 and v2 may be selected to be larger than a lower bound for a tuning speed at which I_{w1} and I_{w2} will be tuned during operation of the first optoelectronic device 100a. Such lower bound for the tuning speed may be determined based on an application or a customer requirement. In various implementations, the tuning speed at which I_{w1} or I_{w2} are tuned may be measured as a rate of change of the current I_{w1} or I_{w2} (expressed as ampere per second), or the tuning speed at which I_{w1} or I_{w2} are switched from one point along a path comprising discrete points of the wavelength map to the next point along the path (expresses as point per second). In some examples, the lower bound for the tuning speed can be from 200 milliampere per microsecond to 500 milliampere per microsecond, from 500 milliampere per microsecond to 1 milliampere per nanosecond, from 1 milliampere per nanosecond to 10 milliampere per nanosecond, from 10 milliampere per nanosecond to 100 milliampere per nanosecond or any range formed by any of these values or possible or larger or smaller.

In various implementations, the initial points and the final point may be selected such that the resulting adjusted parameters (after reducing Δ below the acceptable wavelength uncertainty), tuning the two currents I_{w1}, I_{w2} from other initial points to a different final point results in a Δ below the acceptable wavelength. In some cases, the initial points may be selected to be extreme point representing the largest or smallest current amplitudes in a wavelength map. For example, the two initial points can be two points at two corners of a wavelength map. FIG. 12C shows examples of current paths that may be used during calibration of apparatus 10 or system 900. In the wavelength map 1214 two current paths 1 and 2 start from corner B and D, respectively, (where one of the wavelength control currents I_{w1} and I_{w2} is at its largest value and the other one is at its smallest value within the selected wavelength ranges), and end at a final point F. In some cases, three or more current paths may be used in a calibration procedure. In the wavelength map 1216, four current paths 1, 2, 3, and 4 start from corners B, C, A, and D, respectively, (where one or both of the wavelength control currents I_{w2} and I_{w1} is at its largest or smallest value within the selected wavelength ranges), and end at a final point F. In some cases, the final point F may be selected to be near a center of a region 1215 defined by the modal boundaries. While paths 1, 2, 3, and 4 in the wavelength maps 1214 and 126 are linear paths (e.g., I_{w1} is a linear function of I_{w2}), in some examples, one or more current paths used for calibration can be nonlinear paths. In the wavelength map 1218, two nonlinear current paths 1 and 2 connect the two corners A and C to the final point F.

In some examples, the apparatus 10 or system 900 may be calibrated using one or more current paths having different start and end points. In these cases, the calibration process may comprise:

Step 1: tuning the one or more wavelength tuning currents (e.g., example I_{w1}, I_{w2} provided to the front and back mirrors) from a starting point to an end point of a selected current path at tuning speed vu, measuring the wavelength of light output by the first optoelectronic device 100a at a time t₁ and then time t₂ after tuning the two currents I_{w1}, I_{w2} to the values corresponding to the final point. In some cases, vᵤ can be equal or larger than an upper bound for tuning speed used in an application. In various implementations, a delay between the t2 and t1 can be from 10 to 50 nanoseconds, from 50 to 100 nanoseconds, from 100 nanoseconds to 1 microseconds, from 1 microseconds to 100 microseconds, from 100 microseconds to 1 milliseconds, or any range formed by these values or larger or smaller values.

Step 2: determining a difference Δ′ between the wavelengths measured at time t₁ and t₂.

Step 3: adjusting one or more control parameters of the electrical circuitry 30 to reduce Δ′.

Step 4: repeating Step 1 and 2.

Step 5: if the last Δ′ is smaller than an acceptable wavelength uncertainty (e.g., smaller than ±1 pm, ±5 pm, ±10 pm, or ±100 pm, or larger or smaller values) using the adjusted values of the control parameters as a factory preset. If the last Δ′ is larger than the acceptable wavelength uncertainty, repeat Steps 1 to 4 until the last Δ′ becomes smaller than the acceptable wavelength uncertainty.

In some cases, steps 1-5 described above may be repeated for two or more selected current paths. In some such cases, the selected current paths may comprise current paths selected based on a specific application and the corresponding wavelength tuning operations that may be used during such an application.

FIG. 12D illustrates an example of wavelength variation measurements that may be performed in steps 1-4 of the above calibration procedure. In this example, to is the time that the two currents I_{w1}, I_{w2} are set values corresponding to the end point of a selected current path (e.g., point F in path 1 of the wavelength map 1214 in FIG. 12C). The wavelength of the output light may be measured at t1 and then again at time t2 after time t1. Before adjusting the control parameters, from time t1 to time t2 the wavelength increases by Δ′₁. After adjusting the control parameters, the wavelength 1220 increases by Δ′₂ within the same time interval. In some cases, Δ′₁ is larger than the acceptable wavelength uncertainty and the control parameters are adjusted to make Δ′₂ smaller than the acceptable wavelength uncertainty.

In some examples, the difference between t0 and t1 can be smaller than 0.1 nanoseconds, smaller than 1 nanoseconds, smaller than 10 nanoseconds, smaller than 100 nanoseconds or in any range formed by any of these values or larger or smaller.

In some examples, the difference between t0 and t2 can be from 100 nanoseconds to 1 microseconds, from 1 microseconds to 10 microseconds, from 10 microseconds to 100 microseconds, from 100 microseconds to 1 milliseconds, from 1 milliseconds to 10 milliseconds, or any ranges formed by these values or larger or smaller values.

As mentioned above, a current path in a wavelength map can be defined by different values of at least two electric currents provided to the first optoelectronic device (the light generating device). In some examples, a current path may comprise discrete electric current values corresponding to predefined discrete wavelength values. In some cases, the predefined discrete wavelength values may be associated with a specific application. An example of such a current path is shown in FIG. 12E. In these implementations, the points in a reference map corresponding to the discrete wavelength values may be used to determine the pairs of values for I_{w1} and I_{w2} that define the current path. In some examples, the steps 1-5 described above may be performed for individual pairs of values for I_{w1} and I_{w2} (the discrete points along the current path) until Δ′ is smaller than the acceptable wavelength uncertainty for a subset, majority, or all discrete points in of current the path.

In some examples, the apparatus 10 or system 900 may be calibrated using a series or a sequence of current paths for a specific application that requires adjusting the wavelength of the light output by the optoelectronic device according to a pre-selected (e.g., user defined) series of wavelengths (e.g., an arbitrary wavelength series). In some such examples, the steps 1-5 described above may be repeated for one or more current paths in the series or sequence of the current paths.

In some examples, the wavelengths measured at individual pairs of values for I_{w1} and I_{w2} (the discrete points along a current path, e.g., the current paths shown in FIGS. 12C and 12E) may be compared to wavelengths corresponding to the same individual pairs of values for I_{w1}, I_{w2} in a reference wavelength map, to determine a wavelength error indicative of a difference between the measured wavelengths and the corresponding wavelengths in the reference wavelength map. In some cases, a circuit parameter of the electrical circuitry 30 may be adjusted to reduce the difference between the measured wavelengths and the corresponding wavelengths in the reference wavelength map bellow a threshold value.

In some implementations, the calibrated values of one or more control parameters obtained by calibrating the system 900 may be used as initial values during calibration of another system similar to system 900. For example, after calibrating a first unit, the resulting calibrated value of a control parameter may be used as an initial value for that control parameter when calibrating the next unit.

### Example Calibration Processes

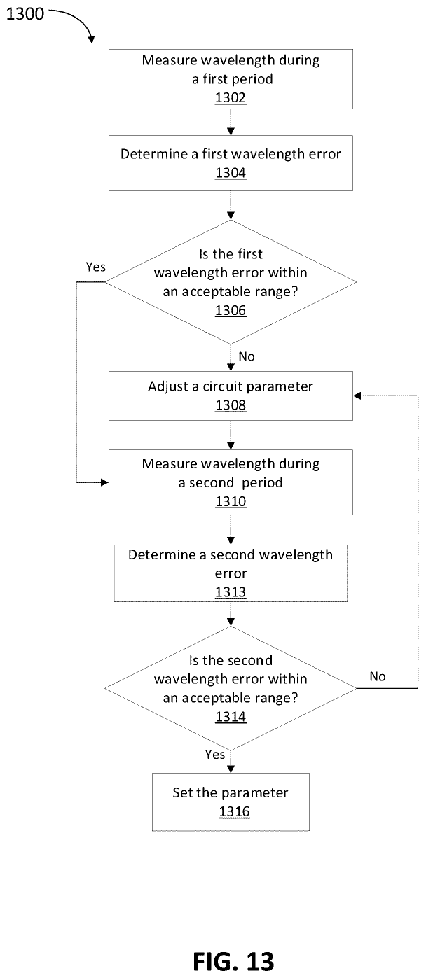

FIG. 13 is a flow diagram illustrating an example method of calibrating an electrical circuitry (e.g., the electrical circuitry 30) configured to control properties of light generated by an optoelectronic device (e.g., the first optoelectronic device 100a) by at least controlling signals (e.g., electrical signals 32b) provided to a second optoelectronic device (e.g., the second optoelectronic device 100b). In some cases, the process 1300 may be performed by at least one electronic processor of the electrical circuitry 30, an electronic processor of a separate calibration system, and/or a user. In some cases, the electrical circuitry 30 or the calibration system may comprise at least one non-transitory memory storing machine-readable data and instructions. In some cases, the electronic processor performs at least a portion of the process 1300 by executing the machine-readable instructions stored in the non-transitory memory. Additionally, or alternatively, the electronic processor may use the data in the non-transitory memory to perform at least a portion of the process 1300. In some examples, data may comprise pre-determined or user specified values of one or more parameters of electrical circuitry.

In some embodiments, the process 1300 may be used to calibrate the electrical circuitry 30 for controlling at least a second electrical signal provided to the second optoelectronic device 100b such that the wavelength of light generated by the first optoelectronic device 100a is stabilized around a constant or time dependent target wavelength when the first optoelectronic device 100a is driven by at least a first signal electrical signal. In some cases, the first electrical signal can be a periodically varying signal or a signal having a predefined temporal profile (e.g., a monotonic temporal profile). In some cases, at least the first electrical signal may be configured to modulate an amplitude of the light output by the first optoelectronic device 100a. In some such cases, the target wavelength of the output light can be constant. In some cases, at least the first electrical signal may be configured to modulate a wavelength of the light output by the first optoelectronic device. In some such cases, the target wavelength of the output light can be a predefined function of time. In either case, the electrical circuitry 30 may be calibrated to control at least a second electrical signal provided to the second optoelectronic device 100b to maintain the wavelength (or center wavelength) of light output by the first optoelectronic signal within a wavelength uncertainty band around and/or centered at the constant or time varying target wavelength.

Additionally, in some cases, the electrical circuitry 30 may be calibrated to control the first signal provided to the optoelectronic device.

In some cases, the calibration process may be used to determine values of one or more circuit parameters of the electrical circuitry that control one or more signals (e.g., currents or voltages) provided to one or more sections of the heat compensating device, to stabilize the wavelength of light generated by the optoelectronic device based at least in part on the target wavelength (constant or time varying). In various implementations, a circuit parameter (also referred to as control parameter) may comprise a parameter of a circuit component, a parameter stored in a non-transitory memory of the electrical circuitry, or a parameter in an algorithm used by the electrical circuitry to control the one or more signals provided to the heat compensating device.

In some cases, during calibration, at least a first electrical signal is provided to a first section of the first optoelectronic device 100a and at least a second electrical signal is provided to a corresponding first section of the second optoelectronic device 100b.

In various implementations, during calibration, a circuit parameter (also referred to as control parameter) of a circuit (e.g., electrical circuit 30) that controls the heat compensating device can be adjusted. In some cases, adjusting the circuit parameter may change a peak value, a phase, or a rate of change of one or more electrical signals provided to one or more sections of the heat compensating device and/or the light generating device. In some cases, adjusting a circuit parameter may comprise changing or configuring one or more electrical signal provided to one or more sections of the heat compensating device based at least in part on (e.g., relative to) one or more signal provided to one or more sections of the light generating device. In some cases, adjusting a circuit parameter may comprise pre-emphasizing and/or post-emphasizing one or more electrical signals provided to one or more sections of the heat compensating device to accelerate the control of the sections of the light generating device.

The process 1300 begins at block 1302 by measuring a first wavelength of light 19 generated and output by the first optoelectronic device 100a during a first period.

At block 1304, the electric processor may determine a first wavelength error between the first wavelength and a first period target wavelength.

At decision block 1306, if the electronic processor determines that the first wavelength error is larger than a wavelength uncertainty limit the process moves to block 1308 and if the electronic processor determines that the first wavelength error is smaller than or equal to the wavelength uncertainty limit the process moves to block 1310.

At block 1308, the electronic processor adjusts at least a first circuit parameter of the electrical circuitry 30 based at least in part on the first wavelength error to reduce a second wavelength error between a second wavelength of light generated by the first optoelectronic device during a second period after the first period, and a second period target wavelength. In some cases, adjusting the at least the first circuit parameter changes at least one signal provided to the second optoelectronic device. Additionally, in some cases, adjusting the at least first circuit parameter changes at least one signal provided to the first optoelectronic device. In some examples, electronic processor may adjust a signal (e.g., a current or voltage) provided to the heat compensating device to stabilize temperatures of one or more sections of the light generating optoelectronic device and subsequently adjust a signal provided to the light generating optoelectronic device (e.g., a phase section of the optoelectronic device) for fine tuning the wavelength of light by the optoelectronic device.

At block 1310, the electronic processor measures a second wavelength of light generated and output by the first optoelectronic device 100a during a second period.

In some cases, measuring the first and second wavelength of light comprises measuring the wavelength of the output light at one or more instants during the first period and the second period, respectively. In some examples, the first wavelength (or the second wavelength) may comprise a single measured wavelength. In some other examples, the first wavelength (or the second wavelength) may comprise an average wavelength determined based on two or more wavelength measurements measured during the first period (or the second period). In various implementations, a duration of the first period and/or the second period can be 0.1, 0.01, 10⁻³, 10⁻⁴ times a period of the first electrical signal provided to the first optoelectronic device 100a or in any range formed by any of these values or larger or smaller.

At block 1312, the electronic processor may determine a second wavelength error (also referred to as the second error) between the second wavelength and a second period target wavelength.

In some cases, the first and the second period target wavelengths can be values stored in a non-transitory memory of the electrical circuitry 30, values received from a user interface of the electrical circuitry 30, or target wavelengths determined by a processor of the electrical circuitry 30 based on a function stored in the non-transitory memory of the electrical circuitry 30. In some cases, the first and the second period target wavelengths are determined by values of at least a first electrical signal provided to the first optoelectronic device 100a during the first and second periods respectively. The magnitude of the first electrical signal may change from the first period to the second period, e.g., according to the function stored in the non-transitory memory. The second period target wavelength can be substantially equal to, smaller than, or larger than, the first period target wavelength.

At decision block 1314, if the electronic processor determines that the second wavelength error is larger than the wavelength uncertainty limit, the process moves back to block 1308 and the electrical circuitry 30 determines that the second wavelength error is smaller than or equal to the wavelength uncertainty limit the process moves to block 1316.

As block 1316, the electrical circuitry 30 sets the circuit parameter as the last adjusted value of the circuit parameter.

In some implementations, a first electrical signal and a third electrical signal are provided to a second section of the first optoelectronic device 100a, and a second electrical signal and a fourth electrical signal are provided to a corresponding second section of the second optoelectronic device 100b. In these implementations, at block 1308 the first circuit parameter and second circuit parameter may be adjusted where the first and second circuit parameters change the second and the fourth electrical signal electrical signals, respectively.

In various implementations, adjusting a circuit parameter at block 1308 may comprise changing a rate of change, a peak value, or a phase of one or more electrical signals provided to one or more sections of the second optoelectronic device 100b (the heat compensating device). In some cases, adjusting a circuit parameter at block 1308 may comprise changing or configuring one or more electrical signal provided to one or more sections of the second optoelectronic device 100b (the heat compensating device) based at least in part on (e.g., relative to) one or more signal provided to one or more sections of the first optoelectronic device 100a. In some cases, adjusting a circuit parameter at block 1308 may comprise changing or configuring one or more electrical signal provided to one or more sections of the second optoelectronic device 100b (the light generating device).

In some cases, adjusting a circuit parameter at block 1308 may comprise pre-emphasizing and/or post-emphasizing one or more electrical signals provided to one or more sections of the second optoelectronic device 100b (the heat compensating device) to accelerate the control of the sections of the first optoelectronic device 100a via heat compensation (as described above with respect to FIGS. 8A and 8B).

In some implementations, the first optoelectronic device may comprise a wavelength tunable laser having at least one optical reflector (mirror) and at least one optical gain section. In some cases, the reflector may comprise an optical grating such as a distributed Bragg grating (DBR) or a sampled grating distributed Bragg grating (SGDBR). In some cases, a section of the first optoelectronic device 100a to which the first electrical signals 32a are provided may comprise the reflector. In some cases, a section of the first optoelectronic device 100a to which the first electrical signals 32a are provided may comprise a phase section.

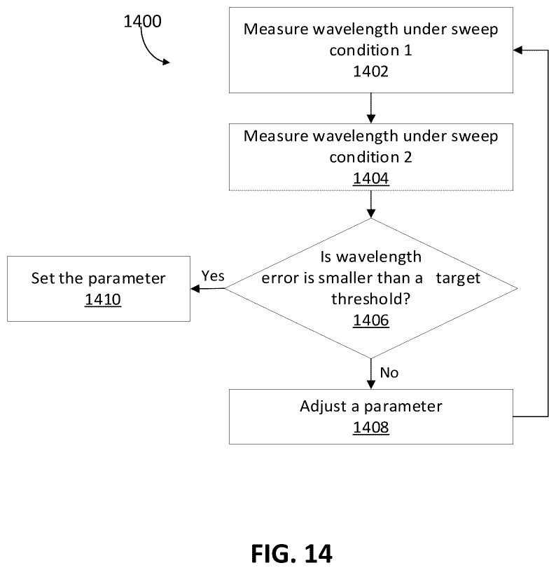

FIG. 14 is a flow diagram illustrating another example method of calibrating an electrical circuitry (e.g., the electrical circuitry 30) configured to control the wavelength of light (e.g., light beam 19) generated by an optoelectronic device (e.g., the first optoelectronic device 100a) by at least controlling signals (e.g., electrical signals 32b) provided to a second optoelectronic device (e.g., the second optoelectronic device 100b). In some cases, the process 1400 may be performed by at least one electronic processor of the electrical circuitry 30, an electronic processor of a separate calibration system, and/or a user who calibrates the optical device. In some cases, the electrical circuitry 30 or the calibration system may comprise at least one non-transitory memory storing machine-readable data and instructions. In some cases, the electronic processor performs at least a portion of the process 1300 by executing the machine-readable instructions stored in the non-transitory memory. Additionally, or alternatively, the electronic processor may use the data in the non-transitory memory to perform at least a portion of the process 1300. In some examples, data may comprise pre-determined or user specified values of one or more parameters of electrical circuitry. Additionally, or alternatively, the electronic processor may use the data in the non-transitory memory to perform at least a portion of the process 1400. In some examples, data may comprise pre-determined values of one or more parameters of electrical circuitry 30. In some examples, the pre-determined values can be user specified values or calculated values based on a model (e.g., an empirical model).

In some embodiments, the process 1400 may be used to calibrate the electrical circuitry 30 for controlling at least a second electrical signal provided to the second optoelectronic device 100b such that the wavelength of light generated by the first optoelectronic device 100a stays within a wavelength uncertainty range from a desired wavelength during a wavelength tuning process. In some cases, at the least the first electrical signal may be configured to change a wavelength of the light output by the first optoelectronic signal according to a predefined wavelength profile. In some such cases, the predefined wavelength profile can be a time varying profile. In either case, the electrical circuitry 30 may be calibrated to control at least a second electrical signal provided to the second optoelectronic device 100b to maintain the wavelength (or center wavelength) of light output by the first optoelectronic signal within a wavelength uncertainty bandwidth around (e.g., centered at) the constant or time varying desired or target wavelength.

Additionally, in some cases, the electrical circuitry 30 may be calibrated to control at the first signal provided to the optoelectronic device.

In some cases, the calibration process may be used by one or more circuit parameters of the electrical circuitry 30 that controls one or more signals (e.g., currents or voltages) provided to one or more sections of the heat compensating device to maintain the wavelength of light generated by the optoelectronic device within an uncertainty wavelength range from the desired or target wavelength. In various implementations, a circuit parameter may comprise a parameter of a circuit component (e.g., a resistance of a variable resistor, a gain of an amplifier, a voltage provided to a component, a value of a logic gate, state of a switch, an attenuation of a variable attenuator, and the like), a parameter stored in a non-transitory memory of the electrical circuitry, or a parameter in an algorithm used by the electrical circuitry to control the one or more signals provided to the heat compensating device.

In some cases, during the calibration process 1400, at least a first electrical signal is provided to a first section of the first optoelectronic device 100a and at least a second electrical signal is provided to a corresponding first section of the second optoelectronic device 100b.

The process 1400 begins at block 1402 where the electronic processor measures a first wavelength of light 19 output by the optoelectronic device 110a under a first wavelength sweep condition. As discussed above, a sweep wavelength condition may comprise adjusting the wavelength of light 19 output by the optoelectronic device 110a from an initial value to a final value via a selected current path. In some cases, the first wavelength sweep condition may comprise adjusting one or more wavelength tuning parameters to specified values via a first path in a wavelength map. For example, the first wavelength sweep condition may comprise adjusting a first electrical current provided to a first mirror of the optoelectronic device from a first initial value to a first specified value via the first path in the wavelength map. In some examples, the first wavelength sweep condition may further comprise adjusting a second current provided to the second mirror of the optoelectronic device from a second initial value to a second specified value, via the first path.

In some cases, the first wavelength sweep condition may be a static wavelength at the final setting after any thermal effects have stabilized or reached equilibrium.

In some cases, the first wavelength sweep condition may comprise adjusting the one or more tuning parameters with a first wavelength tuning speed.

In some cases, a wavelength sweep condition may be associated with timing and order of wavelengths in a sequence of target wavelengths. For example, two different wavelength sweep conditions may comprise: two wavelength maps measured under different raster sequence, different current paths (or sequences) in a selected region of a wavelength map, same or different current paths (or sequences) in different regions of a wavelength map, or wavelengths measured at a point in the wavelength map at different times and/or via different current paths.

In some cases, the first wavelength sweep condition may comprise a slow variation of the wavelength where thermal effects are stabilized after an adjustment and thermal equilibrium is maintained during the wavelength adjustment process.

At block 1404, the electronic processor may measure the wavelength of light 19 output by the optoelectronic device 110a under a second wavelength sweep condition. In some cases, the second wavelength sweep condition may comprise keeping the one or more wavelength tuning parameters at the specified values for a delay period. In some cases, the delay period can be from 1 nanosecond to 10 nanoseconds, from 10 nanoseconds to 100 nanoseconds, from 100 nanoseconds to 1 microsecond, from 1 microsecond to 10 microseconds, from 10 microseconds to 100 microseconds, from 100 microseconds to 1 milliseconds, or any range formed by these values or larger or smaller values.

In some cases, the second wavelength sweep condition may comprise adjusting the one or more wavelength tuning parameters of the optoelectronic device to the specified values via a second path in the wavelength map. For example, the second wavelength sweep condition may comprise adjusting the first electrical current provided to a first mirror of the optoelectronic device from a third initial value to the first specified value via the second path in the wavelength map and adjusting the second current provided to the second mirror of the optoelectronic device from a fourth initial value to the second specified value, via the second path.

In some cases, the second wavelength sweep condition may comprise adjusting the one or more tuning parameters with a second wavelength tuning speed.

In some cases, the first tuning speed can be substantially equal to the first wavelength tuning speed. In some other cases, the first tuning tuning speed can be different from the second wavelength tuning speed.

At the decision block 1406, the electronic processor may determine a first wavelength error comprising a difference between the measured wavelength at block 1402 and the wavelength measure at block 1404. If at the decision block 1406 the electronic processor determines that the wavelength error is larger than a target threshold value, the process 1400 proceeds to block 1408 where one or more parameters that control at least the electrical currents 32b (e.g., the electrical current 705) provided to the optoelectronic device 100b (or another heat compensating device) are adjusted to reduce the wavelength error. Next, the process moves back to block 1402 to repeat the wavelength measurements under the first and the second sweep conditions and determine a new wavelength error associated with the adjusted parameters of the electrical circuit 30. In some cases, adjusting the one or more parameters changes at least one electrical signal provided to the optoelectronic device 100b (or another heat compensating device).

In various examples, the one or more parameters may be adjusted by a user who is performing the calibration procedure (e.g., a factory calibration procedure), a computing system that performs the calibration procedure, or by the electrical circuitry 30. In some cases, one or more parameters may be adjusted based at least in part on a model or algorithm. In some cases, the one or more parameters may be adjusted based at least in part on a measured wavelength map (e.g., a reference wavelength map) or a wavelength difference map.

If at the decision block 1406 the electronic processor determines that the wavelength error is smaller than a target threshold value, the process 1400 moves to block 1410 where the current value of the one or more parameters that control at least the electrical currents 32b (e.g., the electrical current 705) provided to the optoelectronic device 100b (or another heat compensating device) is set as a calibrated value (e.g., a factory calibration value).

In some examples, adjusting the at least one wavelength tuning parameter may comprise tuning a wavelength of the light generated by the first optoelectronic device by a wavelength tuning speed larger than 1 pm/second, larger than 10 pm/second, larger than 100 pm/second, larger than 1 nm/second, larger than 10 nm/second, larger than 100 nm/second, larger than 10³ nm/s, larger than 10⁵ nm/s, larger than 10⁷ nm/s, larger than 10¹⁰ nm/s, or any range formed by any of these values or possibly larger or smaller values.

In some cases, process 1400 may be repeated multiple times based on different sweep conditions to populate a look up table. In some examples, the look up table may comprise values of one or more wavelength tuning currents provided to one or more wavelength tuning sections of the optoelectronic device (e.g., front and back mirrors, a phase section, and the like) for different target wavelengths.

In some cases, the first and second wavelength sweep conditions may comprise a plurality of wavelength points (e.g., wavelength points in a wavelength map) and at block 1406 the electronic processor may use a metric that comprises wavelength errors associated with the plurality of the wavelength points. Accordingly, at block 1408, one or more parameters that control at least the electrical currents 32b (e.g., the electrical current 705) provided to the optoelectronic device 100b (or another heat compensating device) may be adjusted to change the metric to a desired value, to reduce the metric below a threshold values, to increase the metric above a threshold, or to bring metric within a desired range.

In various implementations, the calibration and wavelength tuning methods described above with respect to two wavelength tuning currents provided to one or two mirrors of the light generating optoelectronic device, may comprise adjusting or a wavelength tuning current provided to a phase section of the light generating optoelectronic device.

In various implementations, the calibration and wavelength tuning methods described above with respect to two wavelength tuning currents provided to two sections (e.g., two mirrors) of the light generating optoelectronic device, may additionally comprise adjusting or changing a third wavelength tuning current provided to a third section of the (e.g., phase section) of the light generating optoelectronic device. Accordingly, the wavelength maps and wavelength difference maps described above may comprise three-dimensional wavelength maps. A three-dimensional wavelength map may comprise a wavelength of the output light generated at different values of three different wavelength tuning parameters (e.g., two currents provided to the two mirrors and one current provided to the phase section).

In some examples, four or more parameters may be adjusted to tune the wavelength of light output by the optoelectronic device. In these examples, the methods described above may be expanded to include controlling four or more currents provided to four or more segments of the optoelectronic device and may comprise measuring or using wavelength maps having four or more dimensions.

### Example Embodiments

Various additional example embodiments of the disclosure can be described by the following clauses:

### Examples Group 1

Example 1. An apparatus comprising:
a first optoelectronic device configured to generate optical signals;
a second optoelectronic device in thermal communication with the first optoelectronic device;
at least one detector configured to receive a transmitted portion of the optical signal from the first optoelectronic device and generate a feedback signal indicative of a change in a wavelength of the optical signal; and
electrical circuitry configured to provide at least a first electrical signal to the first optoelectronic device and at least a second electrical signal to the second optoelectronic device to control a temperature of at least one section of the first optoelectronic device;
wherein the electrical circuitry is further configured to adjust at least the second electrical signal based at least in part on the feedback signal.

Example 2. The apparatus of Example 1, wherein the electrical circuitry is configured to adjust the second electrical signal to maintain the wavelength of the optical signal within a wavelength uncertainty limit around at a target wavelength.

Example 3. The apparatus of Example 2, wherein the target wavelength is constant.

Example 4. The apparatus of Example 2, wherein the target wavelength changes over time according to a predefined temporal pattern.

Example 5. The apparatus of any one of the above Examples, wherein the electrical circuitry is further configured to adjust the second electrical signal based at least in part on the first electrical signal.

Example 6. The apparatus of Example 5, wherein the electrical circuitry is configured to adjust the second electrical signal based at least in part on data stored in a non-transitory memory of the apparatus.

Example 7. The apparatus of Example 6, wherein stored data comprises outcomes of a measured current-voltage characteristic of the second optoelectronic device.

Example 8. The apparatus of Example 7, wherein the outcome comprises a resistance, a current, or a heat generation rate of the second optoelectronic device.

Example 9. The apparatus of any one of the above Examples, wherein the electrical circuitry comprises a first electrical circuit that generates the first electrical signal and a second electrical circuitry that generates the second electrical signal.

Example 10. The apparatus of any one of the above Examples, wherein the first optoelectronic device comprises a first optical cavity formed between a first front mirror and a first back mirror, and the second optoelectronic device comprises a second optical cavity formed between a second front mirror and a second back mirror, wherein dimensions of the first optical cavity, the first front mirror, and the first back mirror are identical to those of the second optical cavity, the second front mirror, and the second back mirror.

Example 11. The apparatus of Example 10, wherein the first optical cavity comprises a first gain section and a first phase section, and the second optical cavity comprises a second gain section and a second phase section, wherein dimensions of the first phase section and the first gain section are identical to those of the second phase section and the second gain section.

Example 12. The apparatus of any one of the above Examples, wherein the first electrical signal is provided to a first section of the first optoelectronic device and the second electrical signal is provided to a corresponding first section of the second optoelectronic device.

Example 13. The apparatus of Example 12, wherein the electrical circuitry is further configured to provide a third electrical signal to a second section of the first optoelectronic device and a fourth electrical signal to a corresponding second section the second optoelectronic device.

Example 14. The apparatus of Example 13, wherein the electrical circuitry is configured to adjust a signal property of the fourth electrical signal based at least in part on the feedback signal.

Example 15. The apparatus of any one of the above Examples, wherein the first and second optoelectronic devices have the same design.

Example 16. The apparatus of any one of the above Examples, wherein the first and second optoelectronic devices have different designs.

Example 17. The apparatus of any one of the above Examples, wherein the first and second optoelectronic devices are formed on a common substrate.

Example 18. The apparatus of any one of the above Examples, wherein the first optoelectronic device comprises a wavelength tunable laser.

Example 19. The apparatus of any one of the above Examples, wherein the first optoelectronic device comprises at least one optical reflector, at least one optical gain section, the at least one optical reflector comprising an optical grating.

Example 20. The apparatus of any one of the above Examples, wherein the apparatus is in optical communication with an optical system.

Example 21. The apparatus of Example 20, further comprising an optical beam splitter configured to redirect the portion of the optical signal to the detector and transmit a remaining portion to the optical system.

Example 22. The apparatus of any one of the above Examples, wherein the first optoelectronic device is in thermal communication with the second optoelectronic device via a common substrate on which the first optoelectronic device and the second optoelectronic device are fabricated.

Example 23. The apparatus of any one of the above Examples, further comprising a wavelength selective optical component configured to receive a portion of the optical signal from the first optoelectronic device and generate the transmitted portion of the optical signal.

Example 24. The apparatus of Example 23, wherein the wavelength selective device is further configured to generate a second transmitted portion of the optical signal and the at least one detector comprises a second detector configured to the receive second transmitted portion of the optical signal.

Example 25. The apparatus of any one of the above Examples, wherein the at least one detector comprises a photodetector.

Example 26. The apparatus of Example 23, wherein the wavelength selective optical component comprises an interferometer.

Example 27. The apparatus of Example 26, wherein the wavelength selective optical component comprises an asymmetric Mach-Zehnder interferometer.

Example 28. The apparatus of Example 23, wherein the wavelength selective optical component comprises an integrated photonic device.

Example 29. The apparatus of Example 23, wherein the wavelength selective optical component comprises a fiber optic device.

Example 30. The apparatus of any one of the above Examples, wherein the wavelength selective optical component comprises a fiber optic device.

Example 31. The apparatus of Example 26, wherein the wavelength selective optical component comprises both at least one optical splitter and an asymmetric Mach-Zehnder interferometer.

Example 32. The apparatus of Example 26 or 31, wherein the wavelength selective optical component comprises at least one multimode interferometer.

Example 33. The apparatus of Example 31, wherein the wavelength selective optical component comprises a Planar Light Circuit (PLC) monolithically fabricated on a substrate.

Example 34. The apparatus of Example 31, wherein the wavelength selective optical component comprises a first multimode interferometer having one input port and two output ports and a second multimode interferometer having two input ports and three output ports, and wherein the output ports of the first multimode interferometer are optically connected to the two input ports of the second multimode interferometer via first and second waveguide sections having two different optical path lengths.

Example 35. The apparatus of Example 34, wherein a difference between two different optical path lengths is configured to provide a specified free-spectral range.

Example 36. The apparatus of any one of the above Examples, wherein the electrical circuitry is configured to provide the first electrical signal to a wavelength control section of the first optoelectronic device to control the wavelength of the optical signal.

Example 37. The apparatus of Example 36, wherein the wavelength control section comprises a mirror or a phase section.

Example 38. The apparatus of any one of the above Examples, wherein the electrical circuitry is configured to provide the first electrical signal to a gain section of the first optoelectronic device to control the amplitude of the optical signal.

### Examples Group 2

Example 1. A method of calibrating an electrical circuitry configured to provide at least a first electrical signal to a first optoelectronic device that generates light and at least a second electrical signal to a second optoelectronic device to controllably adjust a temperature of the first optoelectronic device, wherein second optoelectronic device is in thermal communication with the first optoelectronic device; the method comprising:
measuring a first wavelength of light generated by the first optoelectronic device during a first period,
determining a first wavelength error comprising a difference between the first wavelength and a first period target wavelength, and
in response to determining that the first wavelength error is larger than a wavelength uncertainty limit, adjusting at least a first circuit parameter of the electrical circuitry based at least in part on the first wavelength error to reduce a second wavelength error comprising a difference between a second wavelength of light generated by the first optoelectronic device during a second period after the first period, and a second period target wavelength;
wherein adjusting the first circuit parameter changes the second electrical signal, and
wherein the first and the second period target wavelengths are determined by values of the first electrical signal during the first and second periods respectively.

Example 2. The method of Example 1, further comprising measuring a second wavelength of light generated by the first optoelectronic device during the second period and determining the second wavelength difference from the second period target wavelength.

Example 3. The method of Example 2, further comprising in response to determining that the second wavelength error is equal or smaller than the wavelength uncertainty limit, setting the first parameter.

Example 4. The method of Example 2, further comprising in response to determining that the second wavelength error is larger than the wavelength uncertainty limit, adjusting the first circuit parameter or a second circuit parameter based at least in part on the second wavelength error to reduce a third wavelength error comprising a difference between a third wavelength of light generated by the first optoelectronic device during a third period after the second period, and a third period target wavelength.

Example 5. The method of any one of the above Examples, wherein a magnitude of the first electrical signal changes from the first period to the second period.

Example 6. The method of any one of the above Examples, wherein the second period target wavelength is substantially equal to the first period target wavelength.

Example 7. The method of any one of the above Examples, further comprising determining the second period target wavelength using the first period target wavelength and a pre-defined function of time.

Example 8. The method of any one of the above Examples, wherein the first electrical signal is provided to a first section of the first optoelectronic device and the second electrical signal is provided to a corresponding first section of the second optoelectronic device.

Example 9. The method of Example 8, wherein providing the first electrical signal to the first optoelectronic device comprises providing the first electrical signal, and further a third electrical signal to a second section of the first optoelectronic device, and adjusting a first circuit parameter comprises adjusting the first circuit parameter, and further a second circuit parameter, wherein adjusting the second circuit parameter changes a fourth electrical signal electrical signal provided to a second section of the second optoelectronic device.

Example 10. The method of any one of the above Examples, wherein adjusting the first circuit parameter comprises adjusting rate of change, a peak value, or a phase of the second electrical signal.

Example 11. The method of any one of the above Examples, wherein adjusting the first circuit parameter comprises pre-emphasizing the second electrical signal.

Example 12. The method of any one of the above Examples, wherein adjusting the first circuit parameter comprises post-emphasizing the second electrical signal.

Example 13. The method of any one of the above Examples, further comprising measuring a current-voltage characteristic of second optoelectronic device.

Example 14. The method of Example 13, wherein adjusting the first circuit parameter comprises adjusting the second electrical signal based at least in part on outcome of the measured current-voltage characteristic.

Example 15. The apparatus of Example 14, wherein the outcome comprises a resistance, a current, or a heat generation rate of the second optoelectronic device.

Example 16. The method of any one of the above Examples, wherein the first and second optoelectronic devices have the same design.

Example 17. The method of any one of the above Examples, wherein the first and second optoelectronic devices have different designs.

Example 18. The method of any one of the above Examples, wherein the first and second optoelectronic devices are formed on the same substrate.

Example 19. The method of any one of the above Examples, wherein the first optoelectronic device comprises a wavelength tunable laser.

Example 20. The method of any one of the above Examples, wherein the first optoelectronic device comprises at least one optical reflector, at least one optical gain section, the least one optical reflector comprising an optical grating.

Example 21. The method of Example 20, wherein the first electrical signal is provided to the at least one optical reflector of the first optoelectronic device.

Example 22. The method of any one of the above Examples, wherein the electrical circuitry is further configured to adjust the second electrical signal based at least in part on the first electrical signal to maintain wavelength variations of the light generated by the first optoelectronic device within a wavelength uncertainty limit.

Example 23. The method of any one of the above Examples, wherein the second optoelectronic device is in thermal communication with the first optoelectronic device via a common substrate on which both the first and second optoelectronic devices are fabricated.

Example 24. The method of any one of the above Examples, wherein the electrical circuit is configured to provide the first electrical signal to a wavelength control section of the first optoelectronic device to control the wavelength of the optical signal.

Example 25. The method of Example 24, wherein the wavelength control section comprises a mirror or a phase section.

Example 26. The method of any one of the above Examples, wherein the electrical circuitry is configured to provide the first electrical signal to a gain section of the first optoelectronic device to control the amplitude of the optical signal.

### Examples Group 3

Example 1. A method of calibrating electrical circuitry configured to provide at least a first electrical signal to a first optoelectronic device that generates light and at least a second electrical signal to a second optoelectronic device to controllably adjust a temperature of the first optoelectronic device, wherein the second optoelectronic device is in thermal communication with the first optoelectronic device; the method comprising:
changing at least one wavelength tuning parameter of the first optoelectronic device from a first initial value to at least one specified value with a first tuning speed;
measuring a first wavelength of light generated by the first optoelectronic device after changing the at least one wavelength tuning parameter;
measuring a second wavelength of light generated by the first optoelectronic device with a delay after measuring the first wavelength of light;
determining a first wavelength error comprising a difference between the first wavelength and the second wavelength, and
in response to determining that the first wavelength error is larger than a wavelength uncertainty limit, adjusting a value of at least a first circuit parameter of the electrical circuitry based at least in part on the first wavelength error to reduce a subsequent wavelength error;
wherein adjusting the first circuit parameter changes at least the second electrical signal.

Example 2. The method of Example 1, wherein during a wait time between measuring the first and second wavelengths of light the at least one wavelength tuning parameter is substantially equal to the at least one specified value.

Example 3. The method of Example 2, wherein the wait time is larger than 10 nanoseconds.

Example 4. The method of any one of the above Examples, wherein the wavelength uncertainty limit is smaller than 30 pm.

Example 5. The method of any one of the above Examples, wherein the at least one wavelength tuning parameter comprises a first electric current provided to the first optoelectronic device.

Example 6. The method of Example 5, wherein the first tuning speed is larger than 250 milliampere per microsecond.

Example 7. The method of any one of the above Examples, further comprising adjusting the at least one wavelength tuning parameter of the first optoelectronic device from the first initial value to the at least one specified value with a second tuning speed, after measuring the first wavelength and before measuring the second wavelength of light generated by the first optoelectronic device, wherein the second tuning speed is different from the first tuning speed.

Example 8. The method of Example 7, wherein the second tuning speed is greater than the first tuning speed.

Example 9. The method of any one of the above Examples, further comprising adjusting the at least one wavelength tuning parameter of the first optoelectronic device from a second initial value to the at least one specified value after measuring the first wavelength and before measuring the second wavelength of light generated by the first optoelectronic device.

Example 10. The method of any one of the above Examples, further comprising:
adjusting the at least one wavelength tuning parameter of the first optoelectronic device from the first initial value to the at least one specified value after adjusting the at least a first circuit parameter;
measuring a third wavelength of light generated by the first optoelectronic device;
determining a second wavelength error comprising a difference between the first wavelength and the third wavelength, and
in response to determining that the second wavelength error is smaller than the wavelength uncertainty range, setting the adjusted value of the first circuit parameter as a calibrated value.

Example 11. The method of any one of the above Examples, wherein changing the at least one wavelength tuning parameter of the first optoelectronic device from a first initial value to the at least one specified value comprises: changing the first wavelength tuning parameter from the first initial value to a first specified value and changing a second wavelength tuning parameter from a second initial value to a second specified value.

Example 12. The method of any one of the above Examples, wherein adjusting the at least one first wavelength tuning parameter comprises adjusting at least two wavelength tuning parameters from a first pair of initial values to a pair of specified values via a first path in a wavelength map and the method further comprises adjusting at least two wavelength tuning parameters from a second pair of initial values to the pair of specified values via a second path in a wavelength map different from the first path.

Example 13. The method of any of the Examples above, wherein the at least one wavelength tuning parameter comprises an electric current provided to a mirror of the first optoelectronic device.

Example 14. The method of any of the Examples above, wherein the at least one wavelength tuning parameter comprises an electric current provided to a phase section of the first optoelectronic device.

Example 15. The method of any one of the above Examples, further comprising adjusting a signal provided to a phase section of the first optoelectronic device to further reduce the subsequent error.

Example 16. The method of Example 10, further comprising adjusting a signal provided to a phase section of the first optoelectronic device after setting the adjusted value of the first circuit parameter as the calibrated value, to fine tune a wavelength of light generated by the first optoelectronic device.

Example 17. The method of any one of the above Examples, wherein the electrical circuit is configured to provide the first electrical signal to a wavelength control section of the first optoelectronic device to control the wavelength of the optical signal.

Example 18. The method of Example 17, wherein the wavelength control section comprises a mirror or a phase section.

Example 19. The method of any one of the above Examples, wherein the electrical circuitry is configured to provide the first electrical signal to a gain section of the first optoelectronic device to control the amplitude of the optical signal.

### Example Group 4

Example 1. A method of calibrating electrical circuitry configured to provide at least a first electrical signal to a first optoelectronic device that generates light and at least a second electrical signal to a second optoelectronic device to controllably adjust a temperature of the first optoelectronic device, wherein said second optoelectronic device is in thermal communication with the first optoelectronic device, the method comprising:
measuring a first wavelength of light generated by the first optoelectronic under a first wavelength sweep condition;
measuring a second wavelength of light generated by the first optoelectronic under a second wavelength sweep condition;
determining a first wavelength error comprising a difference between the first wavelength and the second wavelength, and
in response to determining that the first wavelength error is larger than a wavelength uncertainty limit, adjusting a value of at least a first circuit parameter of the electrical circuitry based at least in part on the first wavelength error to reduce the first wavelength error;
wherein adjusting the first circuit parameter changes at least the second electrical signal.

Example 2. The method of Example 1, wherein the first wavelength sweep condition comprises adjusting a wavelength tuning parameter of the first optoelectronic device with a first tuning speed and the second wavelength sweep condition comprises adjusting the wavelength tuning parameter with a second speed different from the first tuning speed.

Example 3. The method of Example 2, wherein the wavelength tuning parameter comprises an electric current provided to the first optoelectronic device, the first tuning speed is smaller than 250 milliampere per second, and the second tuning speed is larger than 250 milliampere per microsecond.

Example 4. The method of any one of the above Examples, wherein the first wavelength sweep condition comprises adjusting at least two wavelength tuning parameters of the first optoelectronic device via a first path in a wavelength map and the second wavelength sweep condition comprises adjusting the at least two wavelength tuning parameters via a second path in said wavelength map different than the first path.

Example 5. The method of Example 4, wherein the at least two wavelength tuning parameters comprise an electric current provided to two mirrors of the first optoelectronic device.

Example 6. The method of Example 4, wherein at least one of the at least two wavelength tuning parameters comprises an electric current provided to a phase section of the first optoelectronic device.

Example 7. The method of any one of the above Examples, wherein the first and second wavelength sweep conditions comprise changing at least one wavelength tuning parameter from an initial value to a specified value.

Example 8. The method of Example 7, wherein the wavelength tuning parameter comprises an electric current provided to a mirror of the first optoelectronic device.

Example 9. The method of Example 7, wherein the wavelength tuning parameter comprises an electric current provided to a phase section of the first optoelectronic device.

Example 10. The method of any one of the above Examples, wherein the wavelength uncertainty limit is smaller than 30 pm.

Example 11. The method of any one of the above Examples, wherein the first wavelength sweep condition comprises adjusting at least two wavelength tuning parameters via a path in a wavelength map with a first tuning speed and the second wavelength sweep condition comprises adjusting the at least two wavelength tuning parameters via the same path with a second tuning speed different from the first tuning speed.

Example 12. The method of any one of Examples 4 and 11, wherein the first path, the second path and the path comprise current paths, wherein a current path is associated with at least two electric currents provided to the first optoelectronic device.

Example 13. The method of Example 12, wherein the current path comprises discrete electric current values corresponding to predefined discrete wavelength values.

Example 14. The method of any one of the above Examples, wherein the first wavelength sweep condition comprises adjusting at least two wavelength tuning parameters from a pair of initial values to a pair of target values and the second wavelength sweep condition comprises maintaining the at least two wavelength tuning parameters at the pair of target values for a wait time.

Example 15. The method of Example 14, wherein the wait time is larger than 10 nanoseconds.

Example 16. The method of any one of the above Examples, wherein the electrical circuit is configured to provide the first electrical signal to a wavelength control section of the first optoelectronic device to control the wavelength of the optical signal.

Example 17. The method of Example 16, wherein the wavelength control section comprises a mirror or a phase section.

Example 18. The method of any one of the above Examples, wherein the electrical circuitry is configured to provide the first electrical signal to a gain section of the first optoelectronic device to control the amplitude of the optical signal.

### Example Group 5

Example 1. A method of calibrating electrical circuitry configured to provide at least a first electrical signal to a first optoelectronic device that generates light and at least a second electrical signal to a second optoelectronic device to controllably adjust a temperature of the first optoelectronic device, wherein the second optoelectronic device is in thermal communication with the first optoelectronic device; the method comprising:
changing at least one wavelength tuning parameter of the first optoelectronic device from a first initial value to a first specified value;
measuring a first wavelength of light generated by the first optoelectronic device after changing the at least one wavelength tuning parameter to the first specified value;
determining a first wavelength error comprising a difference between the first wavelength and a third wavelength,
in response to determining that the first wavelength error is larger than a wavelength uncertainty limit, adjusting a value of at least a circuit parameter of the electrical circuitry based at least in part on the first wavelength error;
changing the at least one wavelength tuning parameter of the first optoelectronic device from a second initial value to a second specified value;
measuring a second wavelength of light generated by the first optoelectronic device with a delay after changing the at least one wavelength tuning parameter to the second specified value;
determining a second wavelength error comprising a difference between the second wavelength and a fourth wavelength;
in response to determining that the second wavelength error is larger than a wavelength uncertainty limit, adjusting a value of at least a circuit parameter of the electrical circuitry based at least in part on the second wavelength error;
wherein adjusting the first circuit parameter and the second first circuit parameter changes at least the second electrical signal.

Example 2. The method of Example 1, wherein the first and the second specified values are identical.

Example 3. The method of any one of Examples above, wherein the first and the second specified values correspond to a first specified wavelength and a second specified wavelength, respectively.

Example 4. The method of any one of Examples above, wherein the at least one wavelength tuning parameter comprises at least two electric currents provided to the first optoelectronic device.

Example 5. The method of Example, wherein the first and second specified values comprise a first pair of electric current values and a second pair of electric current values, respectively.

Example 6. The method of Example 5, wherein the first and second pair of electric current values are current values along a current path in a wavelength map, wherein the current path comprises discrete electric current values corresponding to predefined discrete wavelength values.

Example 7. The method of any of Examples above, wherein the third wavelength and the fourth wavelength are wavelengths corresponding to the first and the second specified values of the wavelength tuning parameters, in a reference wavelength map.

Example 8. The method of any of Examples above, wherein the method comprises determining the third and the fourth wavelengths by measuring the wavelength length of light after a wait time after measuring the first wavelength and the second wavelength, respectively.

Example 9. The method of Example 8, wherein the wait time is larger than 10 nanoseconds.

### Terminology

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degrees, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

The methods described herein are performed, in some examples, by software in machine readable form on a tangible, non-transitory storage medium, e.g., in the form of a computer program comprising computer program code adapted to perform the operations of one or more of the methods described herein when the program is run on a computer and where the computer program may be embodied on a non-transitory computer readable medium. The software is suitable for execution on a parallel processor or a serial processor such that the method operations may be carried out in any suitable order, or simultaneously.

This acknowledges that software is a valuable, separately tradable commodity. It is intended to encompass software, which runs on or controls “dumb” or standard hardware, to carry out the desired functions. It is also intended to encompass software which “describes” or defines the configuration of hardware, such as HDL (hardware description language) software, as is used for designing silicon chips, or for configuring universal programmable chips, to carry out desired functions.

Those skilled in the art will realize that storage devices utilized to store program instructions are optionally distributed across a network. For example, a remote computer is able to store an example of the process described as software. A local or terminal computer is able to access the remote computer and download a part or all of the software to run the program. Alternatively, the local computer may download pieces of the software as needed, or execute some software instructions at the local terminal and some at the remote computer (or computer network). Those skilled in the art will also realize that by utilizing conventional techniques known to those skilled in the art that all, or a portion of the software instructions may be carried out by a dedicated circuit, such as a digital signal processor (DSP), programmable logic array, or the like.

Any range or device value given herein may be extended or altered without losing the effect sought, as will be apparent to the skilled person.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one embodiment or may relate to several embodiments. The embodiments are not limited to those that solve any or all of the stated problems or those that have any or all of the stated benefits and advantages. No single feature or group of features is necessary or indispensable to every embodiment.

Any processes, blocks, states, steps, or functionalities in flow diagrams described herein and/or depicted in the attached figures should be understood as potentially representing code modules, segments, or portions of code which include one or more executable instructions for implementing specific functions (e.g., logical or arithmetical) or steps in the process. The various processes, blocks, states, steps, or functionalities can be combined, rearranged, added to, deleted from, modified, or otherwise changed from the illustrative examples provided herein. In some embodiments, additional or different computing systems or code modules may perform some or all of the functionalities described herein. The methods and processes described herein are also not limited to any particular sequence, and the blocks, steps, or states relating thereto can be performed in other sequences that are appropriate, for example, in serial, in parallel, or in some other manner. Tasks or events may be added to or removed from the disclosed example embodiments. Moreover, the separation of various system components in the implementations described herein is for illustrative purposes and should not be understood as requiring such separation in all implementations. It should be understood that the described program components, methods, and systems can generally be integrated together in a single computer product or packaged into multiple computer products. Many implementation variations are possible.

What is claimed is:

1. An apparatus comprising:
a first optoelectronic device configured to generate optical signals;
a second optoelectronic device in thermal communication with the first optoelectronic device;
at least one detector configured to receive a transmitted portion of the optical signals from the first optoelectronic device and generate a feedback signal indicative of a change in a wavelength of the optical signals; and
electrical circuitry configured to provide at least a first electrical signal to the first optoelectronic device and at least a second electrical signal to the second optoelectronic device to control a temperature of at least one section of the first optoelectronic device;
wherein the electrical circuitry is further configured to adjust at least the second electrical signal based at least in part on the feedback signal.

2. The apparatus of claim 1, wherein the electrical circuitry is configured to adjust the second electrical signal to maintain the wavelength of the optical signals within a wavelength uncertainty limit around at a target wavelength.

3. The apparatus of claim 2, wherein the target wavelength is constant.

4. The apparatus of claim 2, wherein the target wavelength changes over time according to a predefined temporal pattern.

5. The apparatus of claim 1, wherein the electrical circuitry is further configured to adjust the second electrical signal based at least in part on the first electrical signal.

6. The apparatus of claim 5, wherein the electrical circuitry is configured to adjust the second electrical signal based at least in part on data stored in a non-transitory memory of the apparatus.

7. The apparatus of claim 6, wherein stored data comprises outcome of a measured current-voltage characteristic of the second optoelectronic device.

8. The apparatus of claim 1, wherein the first optoelectronic device comprises a first optical cavity formed between a first front mirror and a first back mirror, and the second optoelectronic device comprises a second optical cavity formed between a second front mirror and a second back mirror, wherein dimensions of the first optical cavity, the first front mirror, and the first back mirror are identical to those of the second optical cavity, the second front mirror, and the second back mirror.

9. The apparatus of claim 8, wherein the first optical cavity comprises a first gain section and a first phase section, and the second optical cavity comprises a second gain section and a second phase section, wherein dimensions of the first phase section and the first gain section are identical to those of the second phase section and the second gain section.

10. The apparatus of claim 1, wherein the first electrical signal is provided to a first section of the first optoelectronic device and the second electrical signal is provided to a corresponding first section of the second optoelectronic device.

11. The apparatus of claim 1, wherein the first and second optoelectronic devices have the same design.

12. The apparatus of claim 1, wherein the first and second optoelectronic devices have different designs.

13. The apparatus of claim 1, wherein the first and second optoelectronic devices are formed on a common substrate.

14. The apparatus of claim 1, wherein the first optoelectronic device comprises a wavelength tunable laser.

15. The apparatus of claim 13, wherein the first optoelectronic device is in thermal communication with the second optoelectronic device via the common substrate on which the first optoelectronic device and the second optoelectronic device are fabricated.

16. The apparatus of claim 1, further comprising a wavelength selective optical component configured to receive a portion of the optical signals from the first optoelectronic device and generate the transmitted portion of the optical signals.

17. The apparatus of claim 16, wherein the wavelength selective optical component is further configured to generate a second transmitted portion of the optical signals and the at least one detector comprises a second detector configured to receive the second transmitted portion of the optical signals.

18. The apparatus of claim 16, wherein the wavelength selective optical component comprises a Planar Light Circuit (PLC) monolithically fabricated on a substrate, PLC comprising an optical interferometer.

19. The apparatus of claim 18, wherein the optical interferometer comprises at least one of a multimode interferometer (MMI), an optical splitter, or an asymmetric Mach-Zehnder interferometer.

20. The apparatus of claim 19, wherein the PLC comprises a first multimode interferometer having one input port and two output ports, a second multimode interferometer having two input ports and three output ports, and wherein the output ports of the first multimode interferometer are optically connected to the two input ports of the second multimode interferometer via first and second waveguide sections having two different optical path lengths.
